(19) United States
(12) Patent Application Publication
(10) Pub. No.: US 2012/0048377 A1
(43) Pub. Date: Mar. 1, 2012

(54) PHOTOSENSITIVE OPTOELECTRONIC DEVICES COMPRISING POLYCYCLIC AROMATIC COMPOUNDS

(75) Inventors: Kevin Norman Winzenberg, Victoria (AU); Scott Edward Watkins, Victoria (AU); Kimmo Petteri Kemppinen, Victoria (AU); Mark Bown, Victoria (AU)

(73) Assignee: COMMONWEALTH SCIENTIFIC AND INDUSTRIAL RESEARCH ORGANISATION, Campbell (AU)

(21) Appl. No.: 13/254,443

(22) PCT Filed: Mar. 5, 2010
(86) PCT No.: PCT/AU2010/000264

§ 371 Date: Nov. 4, 2011

(30) Foreign Application Priority Data
Mar. 5, 2009 (AU) 2009900963

(51) Int. Cl. H01L 51/46; C07C 13/70; H01L 51/44; C07C 43/215; C07D 409/10; H01B 1/04; C07C 13/62; C07F 7/08

(52) U.S. Cl. 136/263; 585/26; 585/27; 556/431; 568/626; 549/59; 252/510; 257/40; 257/E51.026

(57) ABSTRACT

Photosensitive optoelectronic devices are disclosed including at least one compound comprising at least one polycyclic aromatic substructure wherein the substructures are directly substituted with at least one alkynyl group. The devices exhibit a high degree of stability. In one form the devices may be used in the generation of solar power.

### FIELD OF INVENTION

The present invention relates to photosensitive optoelectronic devices including polycyclic aromatic compounds and to methods of their manufacture. In one form, the photosensitive devices are photovoltaic devices which have application in solar cells. In other forms, the photosensitive devices may be photoconductors or photodetectors.

### BACKGROUND

Solid state heterojunctions, such as the pn junction between p-type and n-type semiconductors, have found widespread application in modern electronics. Solar cells are large area pn junction photodiodes which are optimised to convert light to electrical power. Currently, solar cells are fabricated from conventional inorganic semiconductor materials such as silicon, gallium, cadmium sulphide, etc. The cost of solar cell fabrication utilising these materials is high due to the need for high vacuum processing and, accordingly, their use is limited.

There has been recent interest in the development of organic p-type and n-type semiconductor materials for pn junctions for electronic device applications. Optoelectronic devices that make use of organic materials are becoming increasingly desirable for a number of reasons. Many of the materials used to make such devices are relatively inexpensive, therefore organic optoelectronic devices have the potential for cost advantages over inorganic devices. In addition, the inherent properties of organic materials, such as their flexibility, may make them well suited for particular applications such as fabrication on a flexible substrate. Examples of organic optoelectronic devices include organic light emitting devices (OLEDs), organic transistors/phototransistors, organic photovoltaic cells, and organic photodetectors. For OLEDs, the organic materials may have performance advantages over conventional (i.e., inorganic) materials. For example, the wavelength at which an organic emissive layer emits light may generally be readily tuned with appropriate dopants. For organic transistors/phototransistors, the substrates upon which they are constructed may be flexible, providing for broader applications in industry and commerce. However, one key factor in making solar cells based on organic materials commercially viable is improvement in power efficiency.

The term “organic” includes polymeric materials as well as small molecule organic materials that may be used to fabricate organic devices including optoelectronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendant group on a polymer backbone or as a part of the backbone. Small molecules may also serve as the core moiety of a dendrimer, which consists of a series of chemical shells built on the core moiety. Small molecules generally have a well defined molecular weight, whereas polymers generally do not have a well defined molecular weight.

General background information on low molecular weight organic thin-film photodetectors and solar cells may be found in Peumans et al., “Small Molecular Weight Organic Thin-Film Photodetectors and Solar Cells,” Journal of Applied Physics-Applied Physics Reviews-Focused Review, Vol. 93, No. 7, pp. 3693-3723 (April 2003).

Optoelectronic devices rely on the optical and electronic properties of materials to either produce or detect electromagnetic radiation electronically or to generate electricity from ambient electromagnetic radiation. Photosensitive optoelectronic devices convert electromagnetic radiation into electricity. Photovoltaic (PV) devices or solar cells, which are a type of photosensitive optoelectronic device, are specifically used to generate electrical power. PV devices, which may generate electrical power from light sources other than sunlight, are used to drive power consuming loads to provide, for example, lighting, heating, or to operate electronic equipment such as computers or remote monitoring or communications equipment. These power generation applications also often involve the charging of batteries or other energy storage devices so that equipment operation may continue when direct illumination from the sun or other ambient light sources is not available. As used herein the term “resistive load” refers to any power consuming or storing device, equipment, or system. Another type of photosensitive optoelectronic device is a photoconductor cell. In this function, signal detection circuitry monitors the resistance of the device to detect changes due to the absorption of light. Another type of photosensitive optoelectronic device is a photodetector. In operation a photodetector has a voltage applied and a current detecting circuit measures the current generated when the photodetector is exposed to electromagnetic radiation. A detecting circuit as described herein is capable of providing a bias voltage to a photodetector and measuring the electronic response of the photodetector to ambient electromagnetic radiation. These three classes of photosensitive optoelectronic devices may be characterized according to whether a rectifying junction as defined below is present and also according to whether the device is operated with an external applied voltage, also known as a bias or bias voltage. A photoconductor cell does not have a rectifying junction and is normally operated with a bias. A PV device has at least one rectifying junction and is operated with no bias. A photodetector has at least one rectifying junction and is usually but not always operated with a bias.

Proposed organic semiconducting materials in electroactive devices such as photovoltaic cells have included materials made from a mixture or blend. Some blends have included polymer fullerenes blends. However, some previously proposed materials have not achieved power conversion efficiencies much above 0.5%. Current problems with blended devices include a reduction on carrier mobilities, an increase in charge-trap densities, and difficulties in achieving high crystallinity, order and high purity. Some small molecules used to date are highly reactive with other materials used in the devices and show poor photostability (they degrade with light).

Multilayer heterojunction solar cells fabricated using the alternant polycyclic benzenoid aromatic derivative pentacene as a donor material have been reported to operate at a peak external quantum efficiency of 0.58% at short-circuit condition (Applied Physics Letters, 2004, 85, 5427-5429). Multilayer heterojunction solar cells fabricated using the alternant polycyclic benzenoid aromatic derivative 6,13-bistriisopropylethynylpentacene as a donor material have been reported to operate at a power conversion efficiency of 0.52% (M. T. Lloyd, A. C. Mayer, A. S. Tayi, A. M. Bowen, T. G. Kasen, D. J. Herman, D. A. Mourey, J. E. Anthony, G. G. Malliaras, Organic Electronics, 2006, 7, 243-248). Other pentacene derivatives containing the triisopropylsilylethynyl group as a substituent have also been used as electron donor materials in heterojunction organic photovoltaic devices which have been reported to operate at power conversion efficiencies of up to 0.74% (L. C. Palilis, P. A. Lane, G. P. Kushto, B. Purushothaman, J. E. Anthony, Z. H. Kafifi, Organic Electronics, 2008, 9, 747-752). The performance of solar cells fabricated from electron donating pentacene derivatives and electron accepting fullerene derivatives has been compromised by the propensity of pentacene derivatives to undergo cycloaddition reactions with fullerene derivatives to afford non electroactive adducts (G. P. Miller, J. Briggs, J. Mack, P. A. Lord, M. M. Olmstead, A. L. Balch, Organic Letters, 2003, 5, 4199-4202; M. T. Lloyd, J. E. Anthony, G. G. Malliaris, Materials Today, 2007, 10, 34-41).

WO2009/130991 A1 describes organic thin film solar cell materials with the following formula:

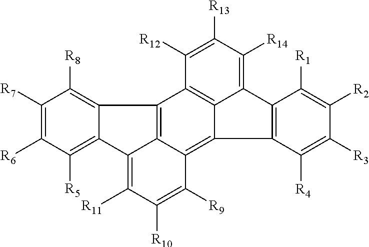

wherein R₁-R₁₄ can be hydrogen and halogen, C₁-C₄₀ alkyl, C₂-C₄₀ alkenyl, C₂-C₄₀ alkynyl, C₆-C₄₀ aryl, C₃-C₄₀ heteroaryl, C₁-C₄₀ alkoxy, an alkylamino group, an arylamino group or aryloxy. However, only a limited number of compounds were prepared and tested in photosensitive devices.

Accordingly, it would be desirable to provide photosensitive optoelectronic devices with higher power conversion efficiencies.

### SUMMARY OF THE INVENTION

In a first aspect of the invention there is provided a photosensitive optoelectronic device including at least one compound comprising at least one polycyclic aromatic substructure wherein at least two of the ring atoms of the said polycyclic aromatic substructure are each common to three rings, said compound being directly substituted with at least one alkynyl group. By “directly substituted with at least one alkynyl group” it is meant that one carbon atom of the carbon carbon triple bond of the alkynyl group is directly bonded to the compound.

In a preferred form of this aspect of the invention the compound is substituted with at least two alkynyl groups wherein at least two of the alkynyl groups are located in non-adjacent substitution positions.

Preferably at least one polycyclic aromatic substructure has at least five aromatic rings, more preferably at least six aromatic rings.

In one embodiment of this aspect of the invention the compound may be further substituted with additional substituents selected from the group consisting of halogen, nitrile and the following optionally substituted moieties: alkyl, cycloalkyl, cycloalkylalkyl, alkoxy, cycloalkoxy, cycloalkylalkoxy, alkenyl, aryl, aryoxy, arylalkyl, heterocyclyl, heterocyclylalkyl, heteroaryl, heteroarylalkyl, alkoxyalkyl, cycloalkoxyalkyl, aryloxyalkyl, haloalkyl, trialkylsilyl, dialkylarylsilyl, alkyldiarylsilyl or triarylsilyl.

In a further embodiment of this aspect of the invention the polycyclic aromatic substructure comprises an alternant polycyclic benzenoid aromatic ring system. Preferably, the alternant polycyclic benzenoid aromatic ring system contains a substructure template selected from the group consisting of:

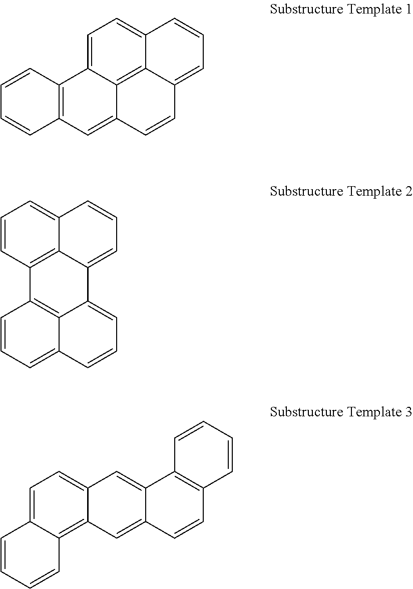

In respect to this embodiment of the invention by substructure template it is meant that the alternant polycyclic benzenoid aromatic ring system comprises at least one of templates 1 to 3 within part of a larger polyaromatic array. Particularly preferred alternant polycyclic benzerioid aromatic ring systems comprising the abovementioned substructure templates are as follows:

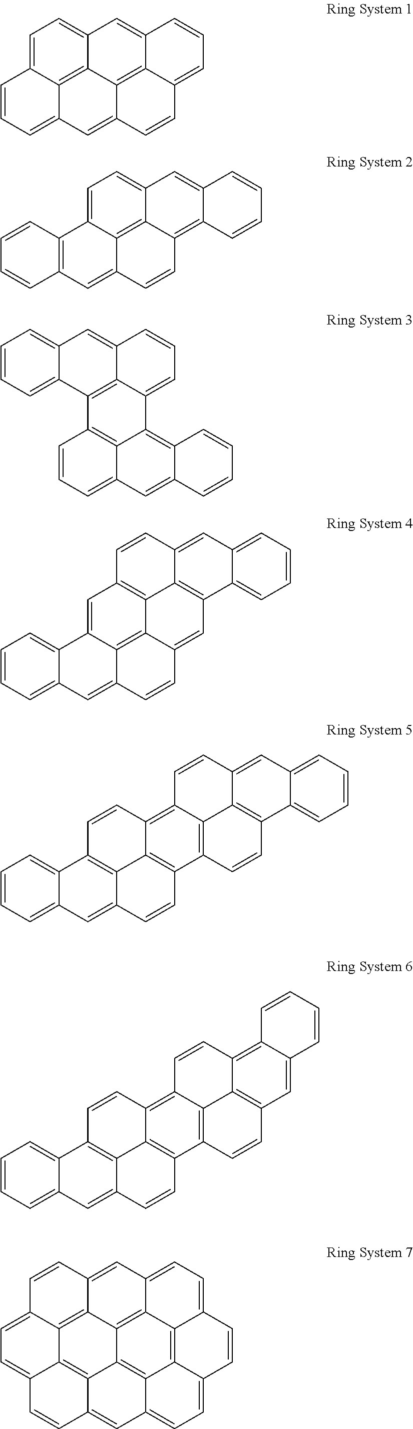

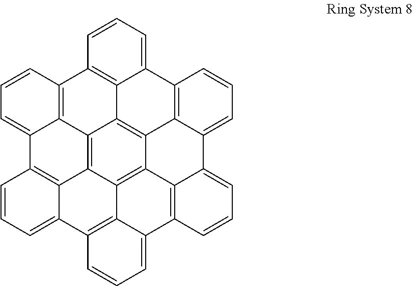

Preferably the alkynyl substituents are of the form —C≡C—X(R)ₙ wherein X is an atom selected from groups IIIa to VIb of the Periodic Table of the Elements and R is independently selected from the group consisting of hydrogen and the following optionally substituted moieties: alkyl, cycloalkyl, cycloalkylalkyl, aryl, arylalkyl, heterocyclyl, heterocyclylalkyl, heteroaryl, heteroarylalkyl, alkoxyalkyl, cycloalkoxyalkyl, aryloxyalkyl, haloalkyl, trialkylsilyl dialkylarylsilyl, alkyldiarylsilyl and triarylsilyl and n is an integer from 1 to v−1 wherein v is the valency of X.

In a further embodiment of this aspect of the invention the compound may have a substructure that comprises rings in addition to or alternative to benzenoid rings.

In one form the substructure may have the following structure:

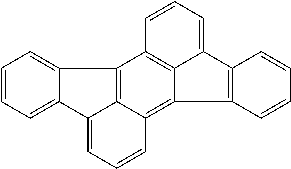

with the proviso that if an alkynyl substituent —C≡C—X(R)ₙ is present at a peripheral carbon atom of this substructure, then X is not a carbon atom.

In a further preferred form of this aspect of the invention the compound is a photosensitive compound. By photosensitive it is meant that the compound contributes to the photocurrent of any suitable device within which the compound is employed.

In one form of the invention the compound may have p-type character within the device. In an alternant form of the invention, the compound may have n-type character within the device.

In a further preferred embodiment the device may comprise one or more species capable of acting as electron donors or electron acceptors.

In a yet further preferred embodiment the compound does not undergo chemical reaction, in particular a carbon-carbon bond forming reaction, with another component of the device.

Another component of the device may include a fullerene or a fullerene derivative. Advantageously, the compound does not undergo a chemical reaction, such as a cycloaddition reaction, with the fullerene or the fullerene derivative.

In one form, the device may be a photovoltaic device.

In an alternate form, the device may be a photoconductive device.

In a further form, the device may be a photodetector.

The device may further comprise a pair of electrodes, and one or more layers of photosensitive semiconducting material between said electrodes. The layer or at least one of the layers of photosensitive material preferably includes at least one compound as defined hereinbefore which is photosensitive and contributes to the photocurrent.

The device may comprise at least two layers of semiconducting materials provided between the electrodes, said layers forming a heterojunction and, preferably, at least one of said layers comprises a photosensitive semiconducting material which includes at least one compound as defined hereinbefore.

Each of said at least two layers may include at least one compound as defined hereinbefore.

Alternatively or additionally, the device may include one or more layers including at least one compound as hereinbefore described which has another function instead of or in addition to at least partly generating a photocurrent, for example, a charge transfer layer.

In a further embodiment, the layer or at least one of the layers of photosensitive semiconducting material may include a mixture or blend of the compound as hereinbefore defined and another organic semiconducting material.

In one form the invention provides advantageously soluble solution processable and/or vacuum deposited electron donating polyaromatic compounds useful for blending with electron accepting derivatives (such as fullerenes) in bulk heterojunction solar cells or fabricating layered heterojunction solar cells containing electron accepting fullerene derivatives.

The compounds are advantageously stable and can provide advantageous layered structures.

In one form the invention provides photovoltaic devices with at least one layer containing a bulk heterojunction in which the polyaromatic hydrocarbon compound does not chemically react with another component to form carbon-carbon bonds. Advantageously, an electron donating polyaromatic hydrocarbon compound may be mixed in a bulk heterojunction layer with one or more electron accepting fullerene derivatives so that the polyaromatic hydrocarbon compound does not chemically react, for example by a cycloaddition reaction, with the fullerene derivatives to form carbon-carbon bonds.

In another form the invention provides a polyaromatic hydrocarbon compound used in a layered heterojunction device structure with compounds so that it does not chemically react with the other components to form carbon-carbon bonds. For example a polyaromatic hydrocarbon compound is used in a layered heterojunction with fullerene derivatives so that the polyaromatic hydrocarbon compound does not undergo chemical reactions to form carbon-carbon bonds with the fullerene derivatives.

In a further aspect of the invention there is provided a use of the photovoltaic device in the generation of solar power.

The invention provides high efficiency heterojunction solar cells based upon solution processable and/or vacuum deposited small molecules. Such cells may be useful in a wide variety of photovoltaic applications.

Throughout this specification, use of the terms “comprises” or “comprising” or grammatical variations thereon shall be taken to specify the presence of stated features, integers, steps or components but does not preclude the presence or addition of one or more other features, integers, steps, components or groups thereof not specifically mentioned.

### BRIEF DESCRIPTION OF THE FIGURES

The present invention will now be described with reference to the accompanying Figures where:

FIGS. 1(a) and (b) show a schematic sectional view of a bilayer structure having one layer including a compound of the invention.

FIGS. 2(a) and (b) show a schematic sectional view of a bilayer structure including two photosensitive layers.

FIGS. 3(a) and (b) show a schematic sectional view of a trilayer structure including at least one photosensitive layer.

FIGS. 4(a) and (b) show a schematic sectional view of a structure including a single photosensitive layer formed from a mixture or blend of materials.

FIG. 5 shows the 1H NMR spectrum of a mixture of TIPSPEN/PCBM 5 minutes after mixing.

FIG. 6 shows the 1H NMR spectrum of a mixture of TIPSPEN/PCBM 24 hours after mixing.

FIG. 7 shows the 1H NMR spectrum of a mixture of TIPSPEN/PCBM ¹H NMR 24 hours after mixing and 30 minutes of sonication at 50° C.

FIG. 8 shows the 1H NMR spectrum of a mixture of compound 1/PCBM ¹H NMR 5 minutes after mixing.

FIG. 9 shows the 1H NMR spectrum of a mixture of compound 1/PCBM ¹H NMR 24 hours after mixing.

FIG. 10 shows the 1H NMR spectrum of a mixture of compound 1/PCBM ¹H NMR 24 hours after mixing and 30 minutes of sonication at 50° C.

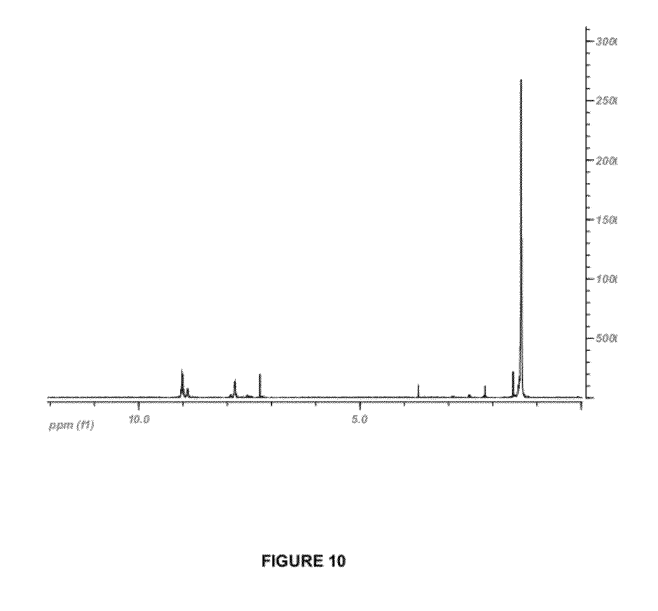

### DETAILED DESCRIPTION OF THE PREFERRED EMBODIMENTS

In one form the invention provides a device that produces an electrical response to light that contains compounds derived from polycyclic aromatic ring systems.

The devices of the invention may contain at least one compound derived from an alternant polycyclic benzenoid aromatic ring system wherein the number of benzene rings that form the alternant polycyclic aromatic ring system is at least six and wherein the alternant polycyclic benzenoid aromatic ring system contains a substructure template chosen from the group consisting of:

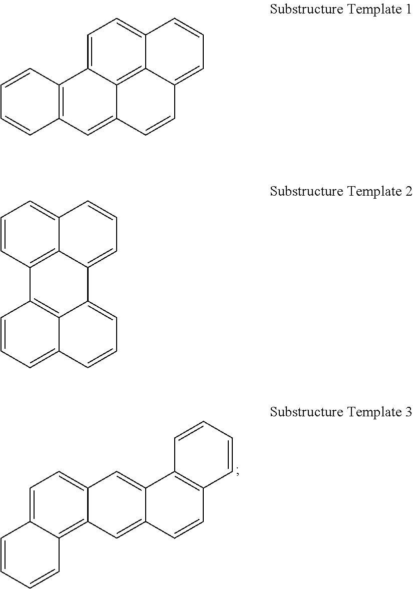

and wherein the alternant polycyclic aromatic ring system is substituted with one or more alkynyl substituents:

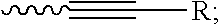

wherein the alkynyl capping group R is selected from the group consisting of hydrogen, and the following optionally substituted moieties: alkyl, cycloalkyl, cycloalkylalkyl, aryl, arylalkyl, heterocyclyl, heterocyclylalkyl, heteroaryl, heteroarylalkyl, alkoxyalkyl, cycloalkoxyalkyl, aryloxyalkyl, haloalkyl, trialkylsilyl dialkylarylsilyl, alkyldiarylsilyl and triarylsilyl and wherein the alternant polycyclic aromatic ring system may be substituted with additional substituents selected from the group consisting of halogen, nitrile and the following optionally substituted moieties: alkyl, cycloalkyl, cycloalkylalkyl, alkoxy, cycloalkoxy, cycloalkylalkoxy, alkenyl, alkynyl, aryl, aryoxy, arylalkyl, heterocyclyl, heterocyclylalkyl, heteroaryl, heteroarylalkyl, alkoxyalkyl, cycloalkoxyalkyl, aryloxyalkyl, haloalkyl, trialkylsilyl dialkylarylsilyl, alkyldiarylsilyl and triarylsilyl.

Some preferred devices of the invention contain at least one compound containing an alternant polycyclic benzenoid ring systems chosen from the group listed below:

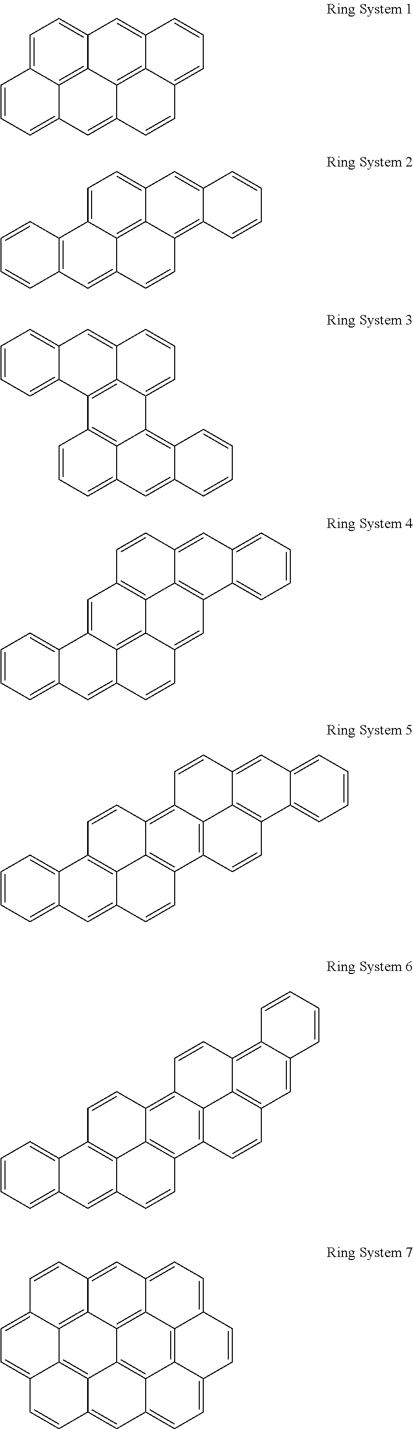

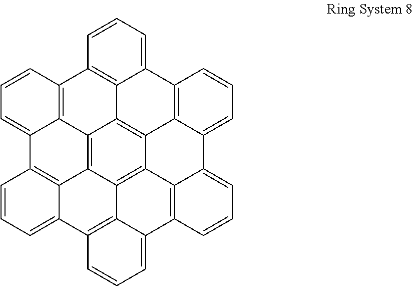

In order to more fully appreciate the invention, the following definitions are provided. As used herein, the following terms are employed as defined below, unless otherwise indicated.

Within this specification “polycyclic aromatic substructure” means a fused polycyclic aromatic array which contains only carbon atoms as vertex atoms of the rings. The polycyclic aromatic substructure may comprise rings having the same number of carbon atoms or rings having different numbers of carbon atoms.

An “alternant polycyclic benzenoid aromatic ring system” is a multi-ring system which contains only fused six-membered benzenoid rings. Examples of an alternant polycyclic benzenoid aromatic ring system are anthracene, tetracene, chrysene, pentacene, pyrene, perylene, pyranthrene, violanthrene, triphenylene, ovalene, and coronene.

“Optionally substituted” means that a functional group is either substituted or unsubstituted, at any available position. Substitution can be with one or more functional groups selected from, e.g., alkyl, alkenyl, alkynyl, cycloalkyl, cycloalkenyl, aryl, heterocyclyl, heteroaryl, formyl, alkanoyl, cycloalkanoyl, aroyl, heteroaroyl, carboxyl, alkoxycarbonyl, cycloalkyloxycarbonyl, aryloxycarbonyl, heterocyclyloxycarbonyl, heteroaryloxycarbonyl, alkylaminocarbonyl, cycloalkylaminocarbonyl, arylaminocarbonyl, heterocyclylaminocarbonyl, heteroarylaminocarbonyl, cyano, hydroxy, alkoxy, cycloalkoxy, aryloxy, heterocyclyloxy, heteroaryloxy, alkanoate, cycloalkanoate, aryloate, heterocyclyloate, heteroaryloate, amino, alkylamino, cycloalkylamino, arylamino, heterocyclylamino, heteroarylamino, alkylcarbonylamino, cycloalkylcarbonylamino, arylcarbonylamino, heterocyclylcarbonylamino, heteroarylcarbonylamino, nitro, thiol, alkylthio, cycloalkylthio, arylthio, heterocyclylthio, heteroarylthio, alkylsulfinyl, cycloalkylsulfinyl, arylsulfinyl, heterocyclysulfinyl, heteroarylsulfinyl, alkylsulfinyl, cycloalkylsulfinyl, arylsulfinyl, heterocyclysulfinyl, heteroarylsulfinyl, halo, haloalkyl, haloaryl, haloheterocyclyl, haloheteroaryl, haloalkoxy, and haloalkylsulfonyl, to name but a few such functional groups.

Preferably, the above described optionally substituted moieties have the following size ranges: (C₁-C₃₀)alkyl, (C₂-C₃₀)alkenyl, (C₂-C₃₀)alkynyl, (C₃-C₁₂)cycloalkyl, (C₃-C₁₀)cycloalkenyl, aryl, heterocyclyl, heteroaryl, (C₁-C₂₀)alkanoyl, aroyl, heterocycloyl, heteroaroyl, (C₁-C₂₀)alkoxycarbonyl, aryloxycarbonyl, heterocyclyloxycarbonyl, heteroaryloxycarbonyl, (C₁-C₂₀)alkylaminocarbonyl, arylaminocarbonyl, heterocyclylaminocarbonyl, heteroarylaminocarbonyl, (C₁-C₃₀)alkoxy, (C₂-C₃₀)alkenyloxy, (C₃-C₁₀)cycloalkoxy, (C₃-C₁₀)cycloalkenyloxy, (C₁-C₃₀)alkoxy(C₁-C₃₀)alkoxy, aryloxy, heterocyclyloxy, (C₁-C₂₀)alkanoate, aryloate, heterocyclyloate, heteroaryloate, (C₁-C₂₀)alkylamino, (C₂-C₂₀)alkenylamino, arylamino, heterocyclylamino, heteroarylamino, (C₁-C₂₀)alkylcarbonylamino, arylcarbonylamino, heterocyclylcarbonylamino, heteroarylcarbonylamino, (C₁-C₃₀)alkylthio, (C₂-C₃₀)alkenylthio, (C₃-C₁₀)cycloalkylthio, (C₃-C₁₀)cycloalkenylthio, arylthio, heterocyclylthio, heteroarylthio, (C₁-C₃₀)alkylsulfinyl, (C₂-C₃₀)alkenylsulfinyl, (C₃-C₁₀)cycloalkylsulfinyl, (C₃-C₁₀)cycloalkenylsulfinyl, arylsulfinyl, heterocyclylsulfinyl, heteroarylsulfinyl, (C₁-C₃₀)alkylsulfonyl, (C₂-C₃₀)alkenylsulfonyl, (C₃-C₁₀)cycloalkylsulfonyl, (C₃-C₁₀)cycloalkenylsulfonyl, arylsulfonyl, heterocyclylsulfonyl, heteroarylsulfonyl, (C₁-C₃₀)haloalkyl, (C₂-C₃₀)haloalkenyl, (C₂-C₃₀)haloalkynyl, (C₁-C₃₀)haloalkoxy, (C₂-C₃₀)haloalkenyloxy, (C₁-C₃₀)haloalkylcarbonylamino, (C₁-C₃₀)haloalkylthio, (C₁-C₃₀)haloalkylsulfinyl and (C₁-C₃₀)haloalkylsulfonyl.

“Alkyl” whether used alone, or in compound words such as alkoxy, alkylthio, alkylamino, dialkylamino or haloalkyl, represents straight or branched chain hydrocarbons ranging in size from one to about 30 carbon atoms, or more. Thus alkyl moieties include, without limitation, moieties ranging in size, for example, from one to about 12 carbon atoms or greater, such as, methyl, ethyl, n-propyl, iso-propyl and/or butyl, pentyl, hexyl, and higher isomers, including, e.g., those straight or branched chain hydrocarbons ranging in size from about 6 to about 20 carbon atoms, or greater.

“Alkenyl” whether used alone, or in compound words such as alkenyloxy or haloalkenyl, represents straight or branched chain hydrocarbons containing at least one carbon-carbon double bond, including, without limitation, moieties ranging in size from two to about 20 carbon atoms or greater, such as, methylene, ethylene, 1-propenyl, 2-propenyl, and/or butenyl, pentenyl, hexenyl, and higher isomers, including, e.g., those straight or branched chain hydrocarbons ranging in size, for example, from about 6 to about 20 carbon atoms, or greater.

“Alkynyl” whether used alone, or in compound words such as alkynyloxy, represents straight or branched chain hydrocarbons containing at least one carbon-carbon triple bond, including, without limitation, moieties ranging in size from, e.g., two to about 20 carbon atoms or greater, such as, ethynyl, 1-propynyl, 2-propynyl, and/or butynyl, pentynyl, hexynyl, and higher isomers, including, e.g., those straight or branched chain hydrocarbons ranging in size from, e.g., about 6 to about 20 carbon atoms, or greater.

“Cycloalkyl” represents a mono- or polycarbocyclic ring system of varying sizes, e.g., from about 3 to about 20 carbon atoms, e.g., cyclopropyl, cyclobutyl, cyclopentyl, cyclohexyl or cycloheptyl. The term cycloalkyloxy represents the same groups linked through an oxygen atom such as cyclopentyloxy and cyclohexyloxy. The term cycloalkylthio represents the same groups linked through a sulfur atom such as cyclopentylthio and cyclohexylthio.

“Cycloalkenyl” represents a non-aromatic mono- or polycarbocyclic ring system, e.g., of about 3 to about 20 carbon atoms containing at least one carbon-carbon double bond, e.g., cyclopentenyl, cyclohexenyl or cycloheptenyl. The term “cycloalkenyloxy” represents the same groups linked through an oxygen atom such as cyclopentenyloxy and cyclohexenyloxy. The term “cycloalkenylthio” represents the same groups linked through a sulfur atom such as cyclopentenylthio and cyclohexenylthio.

The terms, “carbocyclic” and “carbocyclyl” represent a ring system, e.g., of about 3 to about 100 carbon atoms, which may be substituted and/or carry fused rings. Examples of such groups include cyclopentyl, cyclohexyl, or fully or partially hydrogenated phenyl, naphthyl and fluorenyl.

“Aryl” whether used alone, or in compound words such as arylalkyl, aryloxy or arylthio, represents: (i) an optionally substituted mono- or polycyclic aromatic carbocyclic moiety, e.g., of about 6 to about 100 carbon atoms, such as phenyl, naphthyl, anthacenyl, phenanthrenyl, tetracenyl, fluorenyl, pyrenyl, perylenyl, chrysenyl, coronenyl, ovalenyl, picenyl, pyranthrenyl; or, (ii) an optionally substituted partially saturated polycyclic carbocyclic aromatic ring system in which an aryl and a cycloalkyl or cycloalkenyl group are fused together to form a cyclic structure such as a tetrahydronaphthyl, indenyl or indanyl ring.

“Heterocyclyl” or “heterocyclic” whether used alone, or in compound words such as heterocyclyloxy represents: (i) an optionally substituted cycloalkyl or cycloalkenyl group, e.g., of about 3 to about 40 ring members, which may contain one or more heteroatoms such as nitrogen, oxygen, or sulfur (examples include pyrrolidinyl, morpholino, thiomorpholino, or fully or partially hydrogenated thienyl, furyl, pyrrolyl, thiazolyl, oxazolyl, oxazinyl, thiazinyl, pyridyl and azepinyl); (ii) an optionally substituted partially saturated polycyclic ring system in which an aryl (or heteroaryl) ring and a heterocyclic group are fused together to form a cyclic structure (examples include chromanyl, dihydrobenzofuryl and indolinyl); or (iii) an optionally substituted fully or partially saturated polycyclic fused ring system that has one or more bridges (examples include quinuclidinyl and dihydro-1,4-epoxynaphthyl).

“Heteroaryl” whether used alone, or in compound words such as heteroaryloxy represents: (i) an optionally substituted mono- or polycyclic aromatic organic moiety, e.g., of about 5 to about 40 ring members in which one or more of the ring members is/are element(s) other than carbon, for example nitrogen, oxygen or sulfur; the heteroatom(s) interrupting a carbocyclic ring structure and having a sufficient number of delocalized pi electrons to provide aromatic character, provided that the rings do not contain adjacent oxygen and/or sulfur atoms. Typical 6-membered heteroaryl groups are pyrazinyl, pyridazinyl, pyrazolyl, pyridyl and pyrimidinyl. All regioisomers are contemplated, e.g., 2-pyridyl, 3-pyridyl and 4-pyridyl. Typical 5-membered heteroaryl rings are furyl, imidazolyl, oxazolyl, isoxazolyl, isothiazolyl, oxadiazolyl, pyrrolyl, 1,3,4-thiadiazolyl, thiazolyl, thienyl and triazolyl. All regioisomers are contemplated, e.g., 2-thienyl and 3-thienyl. Bicyclic groups typically are benzo-fused ring systems derived from the heteroaryl groups named above, e.g., benzofuryl, benzimidazolyl, benzthiazolyl, indolyl, indolizinyl, isoquinolyl, quinazolinyl, quinolyl and benzothienyl; or, (ii) an optionally substituted partially saturated polycyclic heteroaryl ring system in which a heteroaryl and a cycloalkyl or cycloalkenyl group are fused together to form a cyclic structure such as a tetrahydroquinolyl or pyrindinyl ring.

“Formyl” represents a —CHO moiety.

“Alkanoyl” represents a —C(═O)-alkyl group in which the alkyl group is as defined supra. Preferably ranging in size from about C₂-C₃₀. An example is acyl.

“Aroyl” represents a —C(═O)-aryl group in which the aryl group is as defined supra. Preferably ranging in size from about C₇-C₄₀. Examples include benzoyl and 1- and 2-naphthoyl.

“Heterocycloyl” represents a —C(═O)-heterocyclyl group in which the heterocylic group is as defined supra. Preferably ranging in size from about 4 to 40 ring members.

“Heteroaroyl” represents a —C(═O)-heteroaryl group in which the heteroaryl group is as defined supra. Preferably ranging in size from about 6 to 40 ring members. An example is pyridylcarbonyl.

“Carboxyl” represents a —CO₂H moiety.

“Oxycarbonyl” represents a carboxylic acid ester group —CO₂R which is linked to the rest of the molecule through a carbon atom.

“Alkoxycarbonyl” represents an —CO₂-alkyl group in which the alkyl group is as defined supra. Preferably ranging in size from about C₂-C₃₀. Examples include methoxy- and ethoxycarbonyl.

“Aryloxycarbonyl” represents an —CO₂-aryl group in which the aryl group is as defined supra. Examples include phenoxycarbonyl and naphthoxycarbonyl.

“Heterocyclyloxycarbonyl” represents a —CO₂-heterocyclyl group in which the heterocyclic group is as defined supra.

“Heteroaryloxycarbonyl” represents a —CO₂-heteroaryl group in which the heteroaryl group is as defined supra.

“Aminocarbonyl” represents a carboxylic acid amide group —C(═O)NHR or —C(O)NR₂ which is linked to the rest of the molecule through a carbon atom.

“Alkylaminocarbonyl” represents a —C(═O)NHR or —C(═O)NR₂ group in which R is an alkyl group as defined supra.

“Arylaminocarbonyl” represents a —C(═O)NHR or —C(═O)NR₂ group in which R is an aryl group as defined supra.

“Heterocyclylaminocarbonyl” represents a —C(═O)NHR or —C(═O)NR₂ group in which R is a heterocyclic group as defined supra. In certain embodiments, NR₂ is a heterocyclic ring, which is optionally substituted.

“Heteroarylaminocarbonyl” represents a —C(═O)NHR or —C(═O)NR₂ group in which R is a heteroaryl group as defined supra. In certain embodiments, NR₂ is a heteroaryl ring, which is optionally substituted.

“Cyano” represents a —CN moiety, and “hydroxy” represents the —OH moiety.

“Alkoxy” represents an —O-alkyl group in which the alkyl group is as defined supra. Examples include methoxy, ethoxy, n-propoxy, iso-propoxy, and the different butoxy, pentoxy, hexyloxy and higher isomers.

“Aryloxy” represents an —O-aryl group in which the aryl group is as defined supra. Examples include, without limitation, phenoxy and naphthoxy.

“Alkenyloxy” represents an —O-alkenyl group in which the alkenyl group is as defined supra. An example is allyloxy.

“Heterocyclyloxy” represents an —O-heterocyclyl group in which the heterocyclic group is as defined supra.

“Heteroaryloxy” represents an —O-heteroaryl group in which the heteroaryl group is as defined supra. An example is pyridyloxy.

“Alkanoate” represents an —OC(═O)—R group in which R is an alkyl group as defined supra.

“Aryloate” represents a —OC(═O)—R group in which R is an aryl group as defined supra.

“Heterocyclyloate” represents an —OC(═O)—R group in which R is a heterocyclic group as defined supra.

“Heteroaryloate” represents an —OC(═O)—R group in which R is a heteroaryl group as defined supra.

“Sulfonate” represents an —OSO₂R group that is linked to the rest of the molecule through an oxygen atom.

“Alkylsulfonate” represents an —OSO₂-alkyl group in which the alkyl group is as defined supra.

“Arylsulfonate” represents an —OSO₂-aryl group in which the aryl group is as defined supra.

“Heterocyclylsulfonate” represents an —OSO₂-heterocyclyl group in which the heterocyclic group is as defined supra.

“Heteroarylsulfonate” represents an —OSO₂-heteroaryl group in which the heteroaryl group is as defined supra.

“Amino” represents an —NH₂ moiety.

“Alkylamino” represents an —NHR or —NR₂ group in which R is an alkyl group as defined supra. Examples include, without limitation, methylamino, ethylamino, n-propylamino, iso-propylamino, and the different butylamino, pentylamino, hexylamino and higher isomers.

“Arylamino” represents an —NHR or —NR₂ group in which R is an aryl group as defined supra. An example is phenylamino.

“Heterocyclylamino” represents an —NHR or —NR₂ group in which R is a heterocyclic group as defined supra. In certain embodiments, NR₂ is a heterocyclic ring, which is optionally substituted.

“Heteroarylamino” represents a —NHR or —NR₂ group in which R is a heteroaryl group as defined supra. In certain embodiments, NR₂ is a heteroaryl ring, which is optionally substituted.

“Carbonylamino” represents a carboxylic acid amide group —NHC(═O)R that is linked to the rest of the molecule through a nitrogen atom.

“Alkylcarbonylamino” represents a —NHC(═O)R group in which R is an alkyl group as defined supra.

“Arylcarbonylamino” represents an —NHC(═O)R group in which R is an aryl group as defined supra.

“Heterocyclylcarbonylamino” represents an —NHC(═O)R group in which R is a heterocyclic group as defined supra.

“Heteroarylcarbonylamino” represents an —NHC(═O)R group in which R is a heteroaryl group as defined supra.

“Nitro” represents a —NO₂ moiety.

“Alkylthio” represents a —S-alkyl group in which the alkyl group is as defined supra. Examples include, without limitation, methylthio, ethylthio, n-propylthio, iso-propylthio, and the different butylthio, pentylthio, hexylthio and higher isomers.

“Arylthio” represents an —S-aryl group in which the aryl group is as defined supra. Examples include phenylthio and naphthylthio.

“Heterocyclylthio” represents an —S-heterocyclyl group in which the heterocyclic group is as defined supra.

“Heteroarylthio” represents an —S-heteroaryl group in which the heteroaryl group is as defined supra.

“Sulfinyl” represents an —S(═O)R group that is linked to the rest of the molecule through a sulfur atom.

“Alkylsulfinyl” represents an —S(═O)-alkyl group in which the alkyl group is as defined supra. An example is thioacyl.

“Arylsulfinyl” represents an —S(═O)-aryl group in which the aryl group is as defined supra. An example is thiobenzoyl.

“Heterocyclylsulfinyl” represents an —S(═O)-heterocyclyl group in which the heterocylic group is as defined supra.

“Heteroarylsulfinyl” represents an —S(═O)-heteroaryl group in which the heteroaryl group is as defined supra.

“Sulfonyl” represents an —SO₂R group that is linked to the rest of the molecule through a sulfur atom.

“Alkylsulfonyl” represents an —SO₂-alkyl group in which the alkyl group is as defined supra.

“Arylsulfonyl” represents an —SO₂-aryl group in which the aryl group is as defined supra.

“Heterocyclylsulfonyl” represents an —SO₂ heterocyclyl group in which the heterocyclic group is as defined supra.

“Heteroarylsulfonyl” represents an-SO₂-heterocyclyl group in which the heteroaryl group is as defined supra.

The term “halo,” whether employed alone or in compound words such as haloalkyl, haloalkoxy or haloalkylsulfonyl, represents fluorine, chlorine, bromine or iodine. Further, when used in compound words such as haloalkyl, haloalkoxy or haloalkylsulfonyl, the alkyl may be partially halogenated or fully substituted with halogen atoms which may be independently the same or different. Examples of haloalkyl include, without limitation, —CH₂CH₂F, —CF₂CF₃ and —CH₂CHFCl. Examples of haloalkoxy include, without limitation, —OCHF₂, —OCF₃—OCH₂CCl₃, —OCH₂CF₃ and —OCH₂CH₂CF₃. Examples of haloalkylsulfonyl include, without limitation, —SO₂CF₃, —SO₂CCl₃, —SO₂CH₂CF₃ and —SO₂CF₂CF₃.

Some of the compounds used in the devices of this invention can exist as one or more stereoisomers. The various stereoisomers may include enantiomers, diastereomers and geometric isomers. Those skilled in the art will appreciate that one stereoisomer may be more active than the other(s). In addition, the skilled artisan would know how to separate such stereoisomers. Accordingly, the present invention may include devices that comprise mixtures, individual stereoisomers, and optically active mixtures of the compounds herein discussed.

Some preferred devices of the invention contain at least one compound selected from the group consisting of compounds:

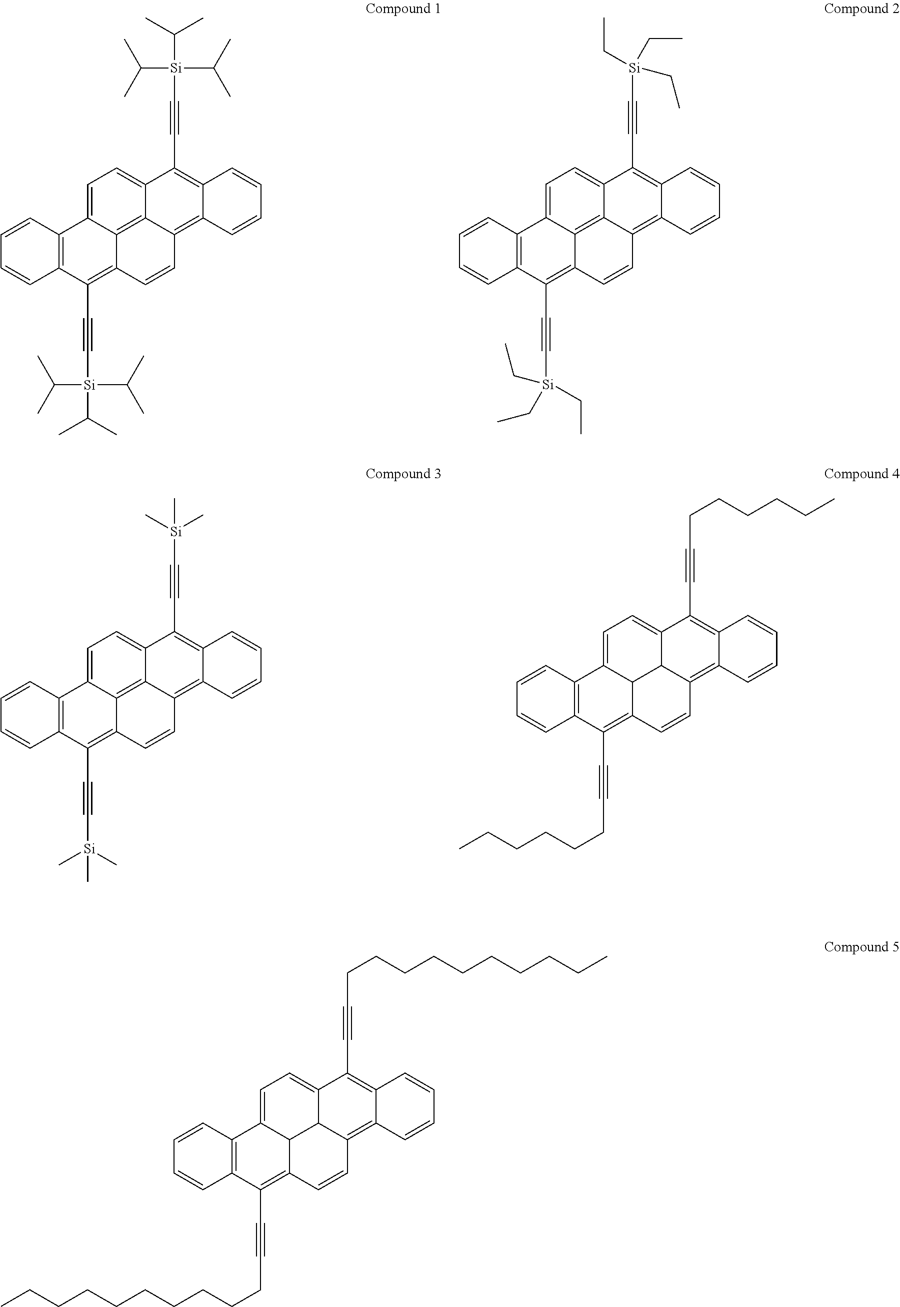

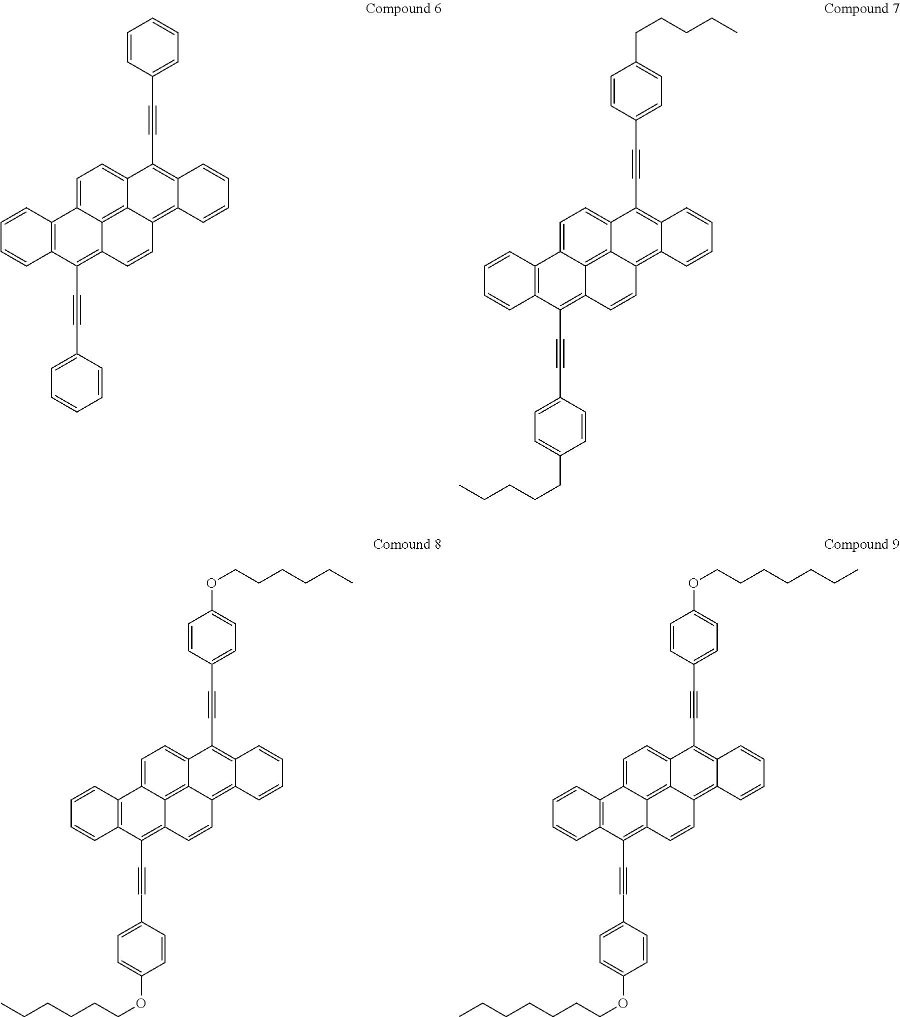

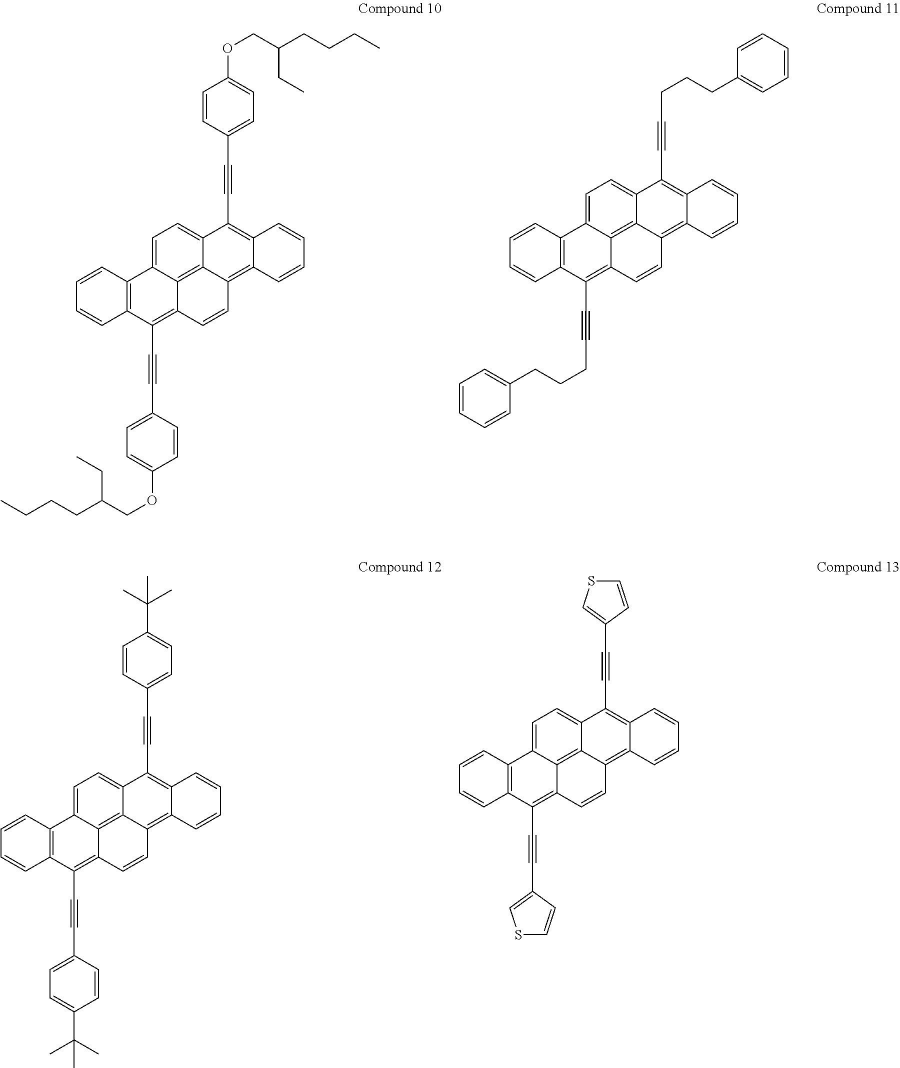

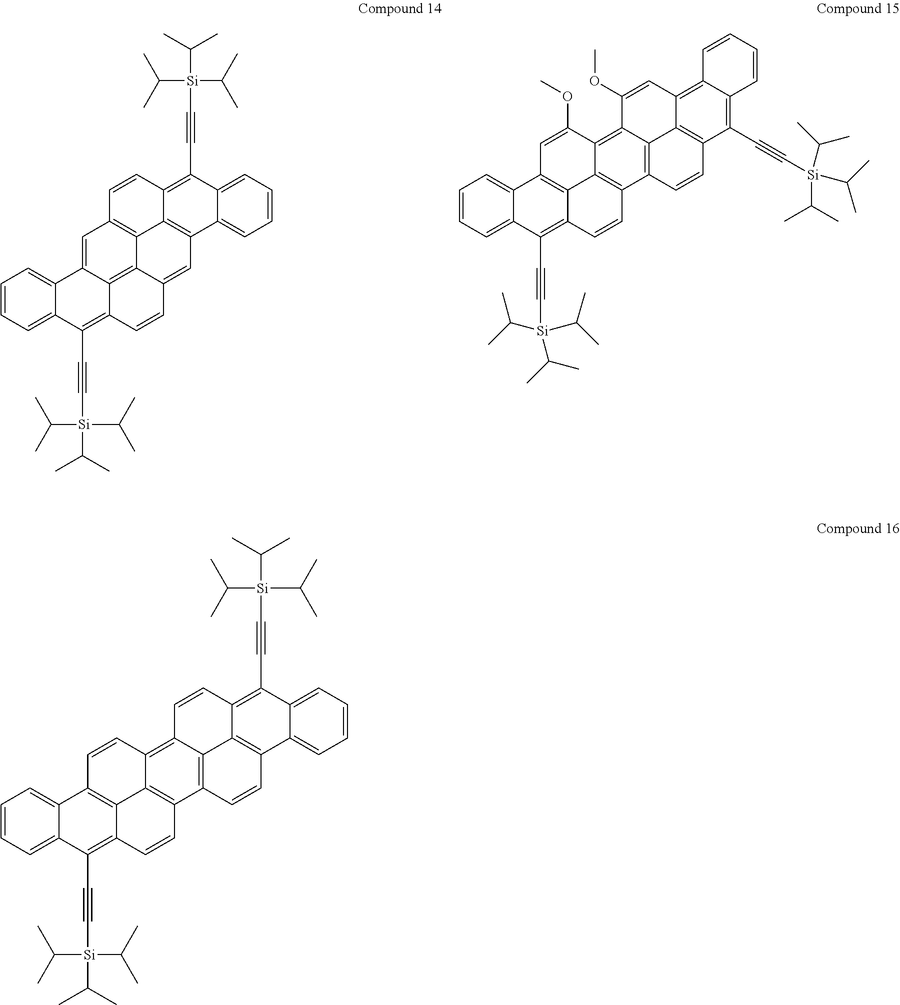

Alternatively, or additionally, the devices of the invention may contain at least one compound derived from a polycyclic aromatic substructure comprising rings having different numbers of carbon atoms.

For example, some preferred devices of the invention may contain the compound 17.

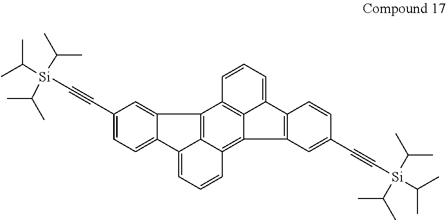

It will be appreciated that numerous variations to the number and size of the rings constituting the polycyclic aromatic substructure would be contemplated by a skilled addressee.

### Device Structures

Possible device structures of devices in accordance with the invention may comprise two electrodes. At least one of these electrodes is at least partially transparent. Between the two electrodes are disposed a layer or a series of layers of compounds, at least one of which contains at least one of the compounds described herein.

The absorption of the devices may be tuned to match the sun (for photovoltaic devices), to match the application (e.g. the absorption of a solar cell may be tuned for cosmetic reasons, e.g. to make a coloured wall that is also a solar cell). The absorption of the devices may also be tuned to match the sensing source (in photodetectors).

The materials in each of the layers may be deposited by, for example, vapour deposition or by solution processes.

The internal structure or morphology of each layer and/or interface and/or the device as a whole may be optimised/varied by techniques such as annealing/heating during deposition, annealing/heating after deposition, the addition of volatile additives which selectively solubilise one of the components plus other techniques known to those skilled in the art.

Examples of possible device structures for the invention are shown in the accompanying drawings.

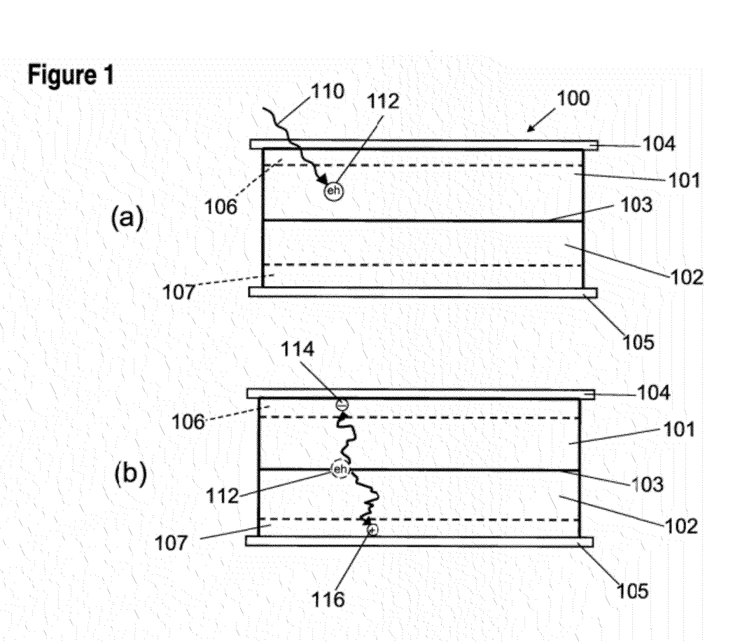

Referring to FIG. 1, there is shown a bilayer photosensitive optoelectronic device 100 including a heterojunction device formed from a first semiconducting layer 101 and a second semiconducting layer 102 which meet at a heterojunction 103. The heterojunction device is sandwiched between first and second electrodes 104, 105. Optionally, charge transfer layers 106, 107 or blocking layers may be provided between the first and second electrodes 104, 105 and the respective first and second semiconducting layers 101, 102.

The first semiconducting layer 101 is a photosensitive layer which preferably includes a compound as described above. The first semiconducting layer 101 may be an electron donor (n-type) material or an electron acceptor (p-type) material with the second semiconducting layer including an electron acceptor (p-type) or an electron donor (n-type) material. For the sake of convenience, as shown in FIG. 1, the semiconducting material of the first layer 101 is an electron transport material, and the semiconducting material of the second layer 102 is a hole transport material. The second semiconducting layer 102 may include any type of semiconducting material, but preferably includes an organic semiconducting material, such as a semiconducting polymer, small molecules or particles or nanoparticles of semiconducting materials.

In modified embodiments, the second semiconducting layer 102 and one or at least one of the optional layers 106, 107 may include a component as described above whose primary function is not to generate a photocurrent, e.g., transporting electrons or holes or charge transfer.

FIG. 1(a) shows the generation of an exciton 112 when a photon 110 with energy greater than E_{g}-E_{b} is absorbed in layer 101, where E_{g} is the band gap of layer 101 and E_{b} is the exciton binding energy. The exciton 112 diffuses to the heterojunction 103 where it dissociates to form an electron 114 and hole 116. Electron 114 percolates to the negative electrode (cathode) 104 and hole 116 to the positive electrode (anode) to generate a current as shown in FIG. 1(b).

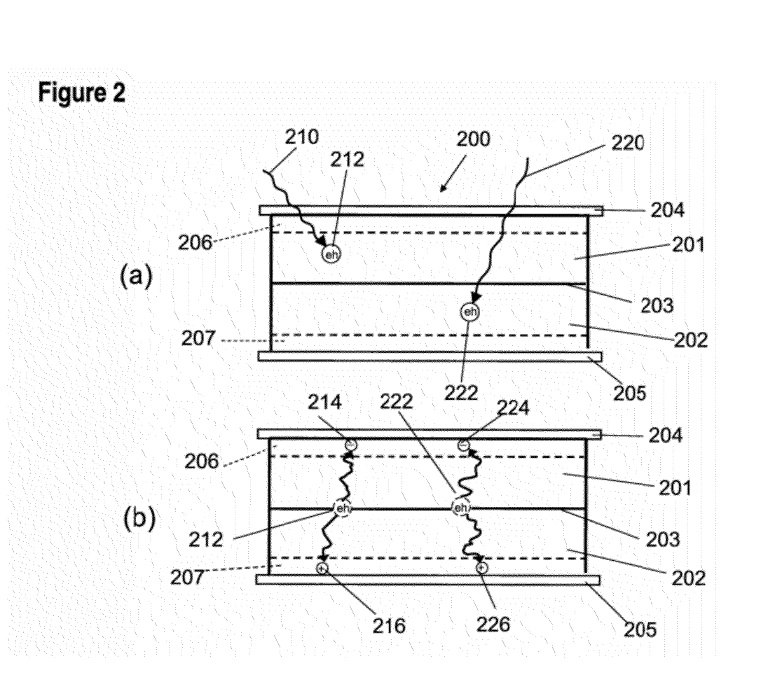

The photosensitive optoelectronic bilayer device 200 of FIG. 2 is similar to that of FIG. 1 in that it has a heterojunction device formed from first and second semiconducting layers 201, 202 which meet at heterojunction 203 sandwiched between first and second electrodes 204, 205 with optional charge transfer/blocking layers 206, 207. The device 200 differs from that of FIG. 1 in that both semiconducting layers 201, 202 are photosensitive layers, and preferably at least one, more preferably both, of the layers includes a compound in accordance with the invention. As shown, the first photosensitive layer 201 is an electron transport material which absorbs photons 210 within a first range of wavelengths (e.g. UV-visible) to product excitons 212. The second photosensitive layer 202 is a hole transport material which absorbs photons 220 within a second range of wavelengths (e.g. infrared) to produce excitons 222 (FIG. 2(a)). As in FIG. 1, the excitons 212, 222 migrate to the heterojunction 203 to form charge carriers in the form of electrons 214, 224 and holes 216, 226 which migrate to the electrodes 204, 205 to generate a current (FIG. 2(b)). As excitons 214,224 can be generated in both semiconducting layers 201, 202 to form charge carriers, there is a potential for greater currents to be generated resulting in greater efficiency.

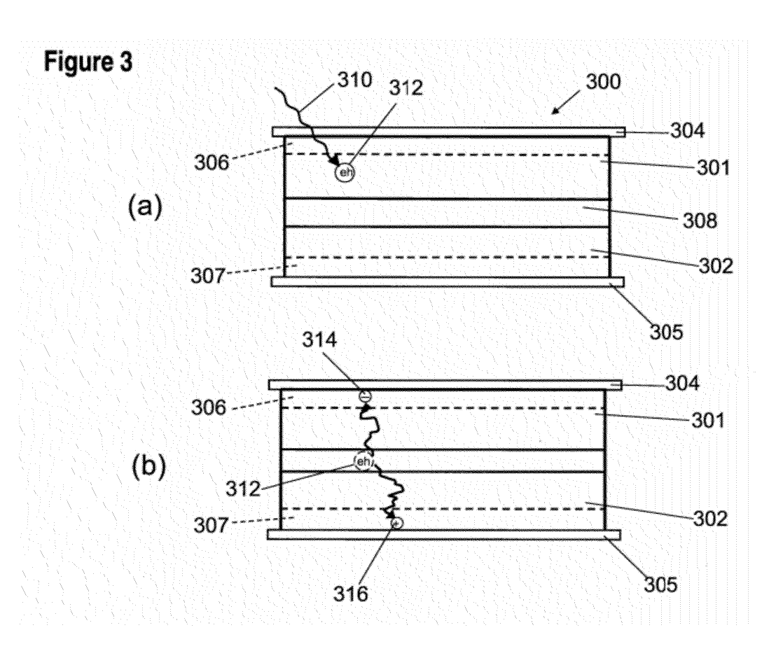

The photosensitive optoelectronic device 300 shown in FIG. 3 is similar to that of FIG. 1 in that it has a heterojunction device including first and second semiconducting layers 301, 302 sandwiched between electrodes 304, 305 with optional charge transfer/blocking layers 306, 307. The device 300 differs from FIG. 1 in that the heterojunction device is a trilayer construction with an interlayer 308 forming the heterojunction between the first and second semiconducting layers 301, 302.

As shown in FIG. 3, only the first semiconducting layer 301 includes a compound in accordance with the invention which absorbs photons 310 to produce excitons 312 (FIG. 3(a)) that dissociate at the heterojunction interlayer 308 to form electrons 314 and holes 316. The second semiconducting layer 302 is formed from a hole transport material, though it will be appreciated that the layer 302 could also include a photosensitive material including, but not limited to, a compound in accordance with the invention. The second layer 302 preferably includes an organic semiconducting material, such as a semiconducting polymer, small molecules or particles of semiconducting material. The interlayer 308 forming the heterojunction could be formed from a single semiconducting material or a mixture/blend of semiconducting materials. The semiconducting materials for interlayer 308 may include a compound described above, small molecules, polymers, particles and/or nanoparticles.

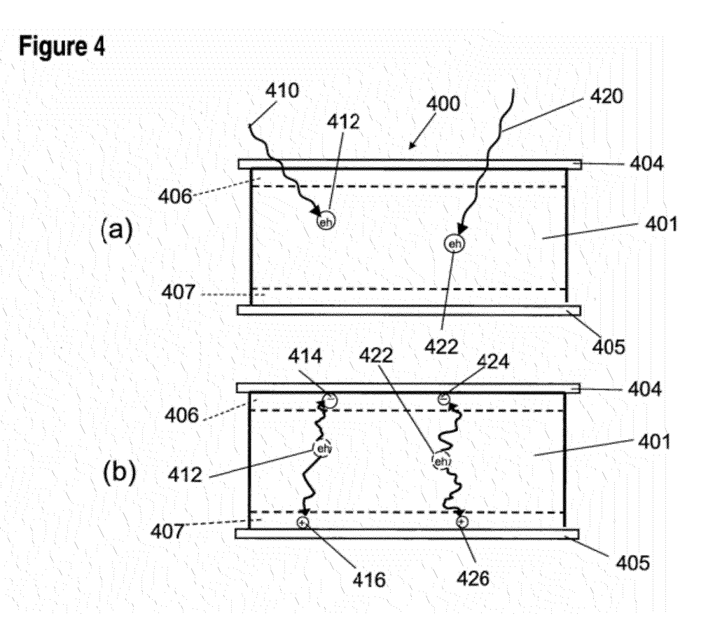

The photosensitive optoelectronic device 400 of FIG. 4 differs from the previous devices in that a single photosensitive semiconducting layer 401 is sandwiched between electrodes 404, 405, with optional charge transfer/blocking layers 406, 407 between the layer 401 and the electrodes 404, 405. The photosensitive semiconducting layer 401 preferably includes at least one photosensitive material including a compound in accordance with the invention. The layer 401 may include a single compound, but is preferably a mixture or blend of a compound according to the invention with another organic semiconducting material in the form of a polymer, small molecule or particles.

As shown in FIG. 4, the semiconducting layer 401 is preferably a mixture/blend including a first photosensitive material that absorbs photons 410 within a first range of wavelengths to produce excitons 412 and a second photosensitive material that absorbs photons 420 within a second range of wavelengths to product excitons 422 (FIG. 4(a)). The layer 401 preferably includes both acceptor (n-type) and donor (p-type) materials so that the heterojunction is within the semiconducting layer 401 itself. As shown in FIG. 4(b), the excitons 412, 422 dissociate within the layer 401 to form electrons 414, 424 and holes 416, 426 which migrate to the respective electrodes 404, 405 (through the optional charge transfer layers 406, 407 where provided) to generate a current.

The thicknesses of each of the semiconducting layers 101, 102; 201, 202; 301, 302; 401, 402 and the interlayer 308, where provided, will typically range from about 1 nm to about 500 nm, more preferably from about 10 nm to 300 nm, and most preferably from about 40 nm to 150 nm.

In further embodiments the devices may also include compounds as hereinbefore described in the form of nanocrystals or quantum dots. Additionally or alternatively, other materials in the form of nanocrystals or quantum dots may be present in addition to the compounds hereinbefore described.

Examples of the Preparation of Compounds that are Useful in Optoelectronic Devices

The compounds derived from alternant polycyclic aromatic ring systems that are useful in devices of the invention can be prepared by a number of methods. Simply by way of example, and without limitation, the compounds can be prepared using one or more of the reaction schemes and methods described below. Some of the compounds useful in this invention are also exemplified by the following preparative examples, which should not be construed to limit the scope of the disclosure in any way.

The following solvents and reagents may be referred to herein by the abbreviations indicated: acetic acid (AcOH), aluminium trichloride (AlCl₃), ammonium chloride (NH₄Cl), boron trichloride (BCl₃), n-butylamine(n-BuNH₂), cuprous chloride (CuCl), 1,2-dichloroethane (DCE), dichloromethane (CH₂Cl₂), diethyl azodicarboxylate (DEAD), diethyl ether (Et₂O), N,N-dimethylethylenediamine[H₂N(CH₂)₂N(CH₃)₂], N,N-dimethylformamide (DMF), dimethyl sulfoxide (DMSO), ethanol (EtOH), ethyl acetate (EtOAc), hydrazine monohydrate (N₂H₄.H₂O), hydrochloric acid (HCl), hydrogen (H₂), iron powder (Fe), magnesium sulfate (MgSO₄), methanol (MeOH), nitric acid (HNO₃), petroleum ether; b.p. 40-60° C. (PE), platinum oxide (PtO₂), potassium permanganate (KMnO₄), sodium acetate (NaOAc), sodium carbonate (Na₂CO₃), sodium hydride (NaH), sodium hydrosulfite (Na₂S₂O₄), sulfuric acid (H₂SO₄), triethylamine(Et₃N), trifluoromethanesulfonic anhydride[(CF₃SO₂)₂O], triphenylphosphine (PPh₃), water (H₂O). RT is room temperature.

Preferred methods of synthesis of the compounds useful in photosensitive optoelectronic devices as described in this invention involve the reaction of quinone substrates with appropriately substituted acetylene derivatives. General methods for the preparation of quinone substrates are described in many publications, for example, Houben-Weyl, Science of Synthesis, Volume 28, Georg Thieme Verlag, Stuttgart, 2006, and references cited therein.

By way of non limiting example, a preferred method of making compounds of the invention involves the reaction of appropriate quinone precursors with Grignard or lithium reagents prepared from acetylene compounds of formula H—CC—R (wherein R is selected from the group consisting of hydrogen, and the following optionally substituted moieties: alkyl, cycloalkyl, cycloalkylalkyl, aryl, arylalkyl, heterocyclyl, heterocyclylalkyl, heteroaryl, heteroarylalkyl, alkoxyalkyl, cycloalkkoxyalkyl, aryloxyalkyl, haloalkyl, trialkylsilyl dialkylarylsilyl, alkyldiarylsilyl, triarylsilyl), followed by reaction with SnCl₂, as described in J. E. Anthony, D. L. Parkin, R. Sean, Organic Letters, 2002, Vol. 4, No. 1, 15-18.

### Example 1

### Preparation of 7,14-bis((triisopropylsilyl)ethynyl)dibenzo[b,def]chrysene, Compound 1

Naphthalene is treated with benzoyl chloride in the presence of AlCl₃, following the procedure described in Scholl, Roland; Neumann, Heinrich, Berichte der Deutschen Chemischen Gesellschaft [Abteilung] B: Abhandlungen (1922), 55B 118-26, to afford 1,5-dibenzoylnapthalene. Following the general procedures described in Steuernagel, Hans, DE3910596, 1990, and Steuernagel, Hans Helmut, and DE3910606, 1990, oxygen gas is bubbled through a heated mixture of 1,5-dibenzoylnapthalene in AlCl₃, NaCl and FeCl₃ to afford dibenzo[b,def]chrysene-7,14-dione, as shown in Scheme 1. Treatment of dibenzo[b,def]chrysene-7,14-dione with lithium triisopropylsilylacetylide followed by reaction with SnCl₂ affords Compound 1.

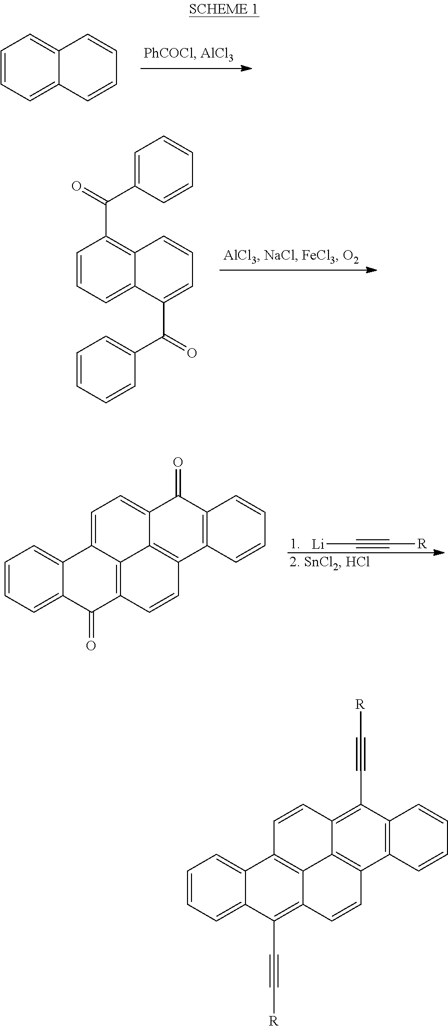

To 30 ml of dry THF under N₂ at −78° C. was added (triisopropylsilyl)acetylene (2.00 ml, 9.00 mmol) followed by 1.6M n-butyllithium in hexane (5.20 ml, 8.25 mmol) dropwise over 5 mins. The solution was stirred for 30 mins at −78° C. after which dibenzo[b,def]chrysene-7,14-dione (500 mg, 1.50 mmol) was added. The reaction was allowed to warm to −20° C. and was stirred for 3 hours. A solution of 2M HCl saturated with SnCl₂.2H₂O (5 ml) was added dropwise at 0° C. and the reaction allowed to stir for 1 hour while warming to room temperature. A saturated solution of NaHCO₃ (50 ml) was added and the resultant slurry was extracted with toluene (2×50 ml). The combined organic layers were washed with H₂O (50 ml) and saturated brine (50 ml), dried over MgSO₄, filtered and concentrated in vacuum to give a red powder. Purification by vacuum chromatography (silica, dichloromethane/petroleum ether 10/90) gave a bright red powder which was recrystallised (dichloromethane/petroleum ether) to give 444 mg of Compound 1 as red/green dichromic plates (0.67 mmol, 46.8%), m.p. 318-321° C. ¹H NMR (400 MHz, CDCl₃): δ 1.35 (m, 42H), 7.85 (m, 4H), 8.94 (m, 2H), 9.04 (m, 6H). ¹³C NMR (400 MHz, CDCl₃): δ 11.65, 19.00, 104.09, 104.14, 116.76, 123.20, 123.29, 123.40, 126.40, 126.95, 127.47, 127.55, 127.79, 127.82, 131.67, 131.90. MS (EI, 70 eV) ink 662.3753 (M⁺, C₄₆H₅₄Si₂ requires 662.3764). Anal. Calcd. for C₄₆H₅₄Si₂ C83.32%, H8.21%. Found C83.51%, H8.48%.

### Example 2

### 7,14-bis((triethylsilyl)ethynyl)dibenzo[b,def]chrysene, Compound 2

To a solution of (triethylsilyl)acetylene (1.61 ml, 9.01 mmol) in anhydrous THF (30 ml) under N₂ at −78° C. was added n-BuLi (1.3 M solution in hexanes, 5.2 ml, 6.76 mmol) dropwise over 2 min. The solution was then stirred at this temperature for 35 min before the addition of dibenzo[b,def]chrysene-7,14-dione (500 mg, 1.50 mmol) in one go. The reaction mixture was warmed to r.t. and stirred for 18 h. A solution of SnCl₂.2H₂O (1.55 g, 6.88 mmol) in wet THF (9 ml) was added dropwise to the mix at 0° C. over 2 min, and then warmed to room temperature within 2 h. It was poured into MeOH (300 ml), stirred and then the precipitate was filtered off and washed with more MeOH. The powder-like solid was redissolved in 200 ml toluene, dried over Na₂SO₄ over night and then put through a short column (silica 0.015-0.040 mm). The solvent was removed and dried in vacuo, which afforded 559 mg (0.97 mmol, 64.5%) of Compound 2. Recrystallisation from 1,4-dioxane (25 ml)/petrol spirit (bp. 40-60° C., 25 ml)/MeOH (25 ml) gave 236 mg of Compound 2 as small dark brown needles; the solvent was removed from the filtrate and the residue was recrystallised from 10 ml heptane/iPrOH to give another crop of 214 mg of Compound 2 (total recovery 450 mg, 80.5%), mp. 300-307° C. ¹H NMR (400 MHz, CDCl₃): δ 0.96 (q, 12H, J=7.9 Hz), 1.31 (t, 18H, J=7.7 Hz), 7.73-7.79 (m, 4H), 8.72-8.91 (m, 8H). ¹³C NMR (400 MHz, CDCl₃): δ 4.84, 7.91, 103.52, 104.80, 116.32, 122.78, 123.14, 123.16, 126.26, 126.77, 127.25, 127.34, 127.54, 127.60, 131.33, 131.57. MS (EI, 70 eV): m/z 578.2814 (M⁺, C₄₀H₄₂Si₂ requires 578.2820). Anal. Calcd. for C₄₀H₄₂Si₂: C82.99%, H7.31%, Si 9.70%. found C82.31%, H7.38%.

### Example 3

### 7,14-bis((trimethylsilyl)ethynyl)dibenzo[b,def]chrysene, Compound 3

To a solution of (trimethylsilyl)acetylene (12.41 ml, 89.74 mmol) in anhydrous THF (300 ml) under N₂ at −78° C. was added n-BuLi (1.1M solution in hexanes, 61.2 ml, 67.30 mmol) dropwise over 10 min. The solution was then stirred at this temperature for 30 min. Dibenzo[b,def]chrysene-7,14-dione (5.001 g, 14.96 mmol) was then added in one portion. The reaction mixture was warmed to +10° C. and stirred for 18 h. A solution of SnCl₂.2H₂O (16.90 g, 75.00 mmol) in aqueous HCl (3 M, 100 ml) was carefully added dropwise to the mix at 0° C., and then warmed to room temperature within 2 h. The reaction mixture was poured into acetonitrile/1M HCl (1.4 L/0.7 L), stirred at r.t. and the red precipitate was filtered off and washed with more acetonitrile (crude yield 6.541 g, 88.4%). Recrystallisation from 1,4-dioxane gave 5.002 g of Compound 3 (10.11 mmol, 67.6% yield) of small orange-red needles, mp. 285.5-288.5° C. ¹H NMR (400 MHz, CDCl₃): δ 0.51 (s, 18H), 7.84-7.86 (m, 4H), 8.85-8.87 (m, 2H), 8.91 (d, 2H, J=9.4 Hz), 8.99-9.03 (m, 4H). ¹³C NMR (400 MHz, CDCl₃): δ 0.28, 102.27, 107.44, 116.38, 123.18, 123.24, 123.33, 126.49, 126.96, 127.49, 127.71, 127.80, 127.87, 131.55, 131.79. MS (EI, 70 eV): m/z 494.1877 (M⁺, C₃₄H₃₀Si₂ requires 494.1881). Anal. Calcd. for C₃₄H₃₀Si₂: C82.54%, H6.11%, Si 11.35%. found C81.86%, H6.07%.

### Example 4

### 7,14-bisoctyn-1-yldibenzo[b,def]chrysene, Compound 4

To 30 ml of dry THF under N₂ at −78° C. was added octyne (1.00 ml, 9.00 mmol) followed by 1.6M ⁿbutyllithium in hexane (5.20 ml, 8.25 mmol) dropwise over 5 mins. The solution was stirred for 30 mins at −78° C. after which dibenzo[b,def]chrysene-7,14-dione (500 mg, 1.50 mmol) was added in one portion. The reaction was allowed to warm to −20° C. and was stirred for 3 hours. A solution of 2M HCl saturated with SnCl₂.2H₂O (5 ml) was added dropwise at 0° C. and the reaction allowed to stir for 1 hour while warming to room temperature. A saturated solution of NaHCO₃ (50 ml) was added and the resultant slurry was extracted with toluene (2×50 ml). The combined organic layers were washed with H₂O (50 ml) and saturated brine (50 ml), dried over MgSO₄, filtered and concentrated in vacuum to give a red powder. Purification by vacuum chromatography (silica, dichloromethane/petroleum ether 10/90) gave 604 mg of Compound 4 a bright red powder (1.16 mmol, 77.4%), m.p. 142-144° C. ¹H NMR (400 MHz, CDCl₃): δ 0.99 (t, 6H), 1.47 (m, 8H), 1.71 (m, 4H), 1.90 (m, 4H), 2.85 (t, 4H), 7.81 (m, 4H), 8.84 (m, 4H), 8.91 (m, 4H). ¹³C NMR (400 MHz, CDCl₃): δ 14.14, 20.39, 22.69, 28.92, 29.15, 31.49, 103.22, 117.45, 122.92, 123.25, 123.58, 126.21, 126.56, 127.01, 127.51, 127.61, 127.77, 131.18, 131.82. MS (EI, 70 eV) m/z 518.2967 (M⁺, C₄₀H₃₈ requires 518.2968). Anal. Calcd. for C₄₀H₃₈C92.62%, H7.38%. Found C90.98%, H7.34%.

### Example 5

### 7,14-bisdodecyn-1-yldibenzo[b,def]chrysene, Compound 5

To 30 ml of dry THF under N₂ at −78° C. was added dodecyne (1.69 g, 9.81 mmol) followed by 1.1M n-butyllithium in hexane (7.25 ml, 8.25 mmol) dropwise over 5 mins. The solution was stirred for 30 mins at −78° C. after which dibenzo[b,def]chrysene-7,14-dione (500 mg, 1.50 mmol) was added in one portion. The reaction was allowed to warm to room temperature and was stirred for 16 hours. A filtered solution of 3M HCl (5 ml) containing SnCl₂.2H₂O (2 g, 8.86 mmol) was added dropwise at 0° C. and the reaction allowed to stir for 3 hours while warming to room temperature. The reaction was quenched with a solution of acetonitrile/H₂O (1/1, 50 ml) and allowed to stir for 5 mins, then poured into a solution of acetonitrile/H₂O (1/1, 150 ml), stirred and a further aliquot of acetonitrile (100 ml) was added. The red precipitate which formed was filtered off and washed with cold acetonitrile (50 ml). Filtration through a silica plug (chloroform) followed by recrystallisation (chloroform/petroleum ether, 2/5 ratio) gave 336 mg of Compound 5 as a red powder (0.533 mmol, 35.4%), m.p. 129-130° C. ¹H NMR (400 MHz, CDCl₃): δ 0.88 (t, 6H), 1.35 (m, 24H), 1.70 (m, 4H), 1.91 (m, 4H), 2.89 (t, 4H), 7.30 (m, 4H), 8.91 (m, 4H), 9.03 (m, 4H). ¹³C NMR (400 MHz, CDCl₃): Was not soluble enough to obtain a carbon spectrum 6 MS (EI, 70 eV) m/z 630.4213 (M⁺, C₄₈H₅₄ requires 630.4220). Anal. Calcd. for C₄₈H₅₄C91.37%, H 8.63%. Found C 90.73%, H 8.73%.

### Example 6

### Preparation of 7,14-bis(4-pentylphenylethynyl)dibenzo[b,def]chrysene, Compound 7

To 30 ml of dry THF under N₂ at −78° C. was added 1-ethynyl-4-pentylbenzene (1.69 g, 9.81 mmol) followed by 1.1M n-butyllithium in hexane (7.25 ml, 8.25 mmol) dropwise over 5 mins. The solution was stirred for 30 mins at −78° C. after which dibenzo[b,def]chrysene-7,14-dione (500 mg, 1.50 mmol) was added in one portion. The reaction was allowed to warm to room temperature and was stirred for 16 hours. A filtered solution of 3M HCl (5 ml) containing SnCl₂.2H₂O (2 g, 8.86 mmol) was added dropwise at 0° C. and the reaction allowed to stir for 3 hours while warming to room temperature. The reaction was quenched with a solution of acetonitrile/H₂O (1/1, 50 ml) and allowed to stir for 5 mins, then poured into a solution of acetonitrile/H₂O (1/1, 150 ml), stirred and a further aliquot of acetonitrile (100 ml) was added. The black precipitate which formed was filtered off and washed with cold acetonitrile (50 ml). Filtration through a silica plug (chloroform) followed by recrystallisation (chloroform/petroleum ether, 2/5 ratio) gave 425 mg of a dark purple powder (0.633 mmol, 44.0%), m.p. 256-257° C. ¹H NMR (400 MHz, CDCl₃): δ 0.94 (t, 6H), 1.39 (m, 8H), 1.71 (m, 4H), 2.72 (t, 4H), 7.32 (d, 2H J=8.00 Hz), 7.78 (d, 2H J=8.00 Hz), 7.87 (m, 4H), 9.04 (m, 8H). ¹³C NMR (400 MHz, CDCl₃): δ 14.07, 22.59, 31.05, 31.51, 36.03, 86.67, 102.14, 116.72, 120.83, 123.10, 123.31, 123.42, 126.41, 126.80, 127.51, 127.64, 127.86, 128.73, 131.11, 131.59, 131.65, 143.88, 153.67. MS (EI, 70 eV) m/z 642.3288 (M⁺, C₅₀H₄₂ requires 642.3281). Anal. Calcd. for C₅₀H₄₂C 93.41%, H 6.59%. Found C 93.40%, H 6.57%.

### Example 7

### Preparation of 8,16-bis((triisopropylsilyl)ethynyl)pyranthrene, Compound 14

To 30 ml of dry THF under N₂ at −78° C. was added (triisopropylsilyl)acetylene (2.00 ml, 9.00 mmol) followed by 1.6M n-butyllithium in hexane (5.20 ml, 8.25 mmol) dropwise over 5 mins. The solution was stirred for 30 mins at −78° C. after which 8,16-pyranthrenedione (610 mg, 1.50 mmol) was added. The reaction was allowed to warm to room temperature and was stirred overnight. A solution of 3M HCl saturated with SnCl₂.2H₂O (5 ml) was added dropwise at 0° C. and the reaction allowed to stir for 1 hour while warming to room temperature. The reaction was quenched with a solution of acetonitrile/H₂O (1/1, 50 ml) and allowed to stir for 5 mins, then poured into a solution of acetonitrile/H₂O (1/1, 150 ml), stirred and a further aliquot of acetonitrile (100 ml) was added. The black precipitate which formed was filtered off and washed with cold acetonitrile (100 ml) then recrystallised from chloroform/pentane (1/3, 200 ml) to give 773 mg of Compound 14 as very small dark purple needles (1.05 mmol, 69.9%), m.p. 397-403° C. ¹H NMR (400 MHz, CDCl₃): δ 1.38 (m, 42H), 7.86 (m, 4H), 8.23 (d, 2H, J=10 Hz), 8.74 (d, 2H, J=9 Hz), 8.90 (d, 2H J 8 Hz), 9.14 (d, 2H, J=8 Hz), 9.41 (s, 2H). ¹³C NMR (400 MHz, CDCl₃): Was not soluble enough to obtain a carbon spectrum. MS (EI, 70 eV) m/z 736.3921 (M, C₅₂H₅₆Si₂ requires 736.3915). Anal. Calcd. for C₅₂H₅₆Si₂ C 84.72%, H 7.66%. Found C 84.95%, H 7.83%

### Example 8

### 16,17-Dimethoxy-5,10-bis((triisopropylsilyl)ethynyl)violanthrene, Compound 15

To 20 ml of dry THF under N₂ at −78° C. was added (triisopropylsilyl)acetylene (1.35 ml, 6.00 mmol) followed by 1.1M n-butyllithium in hexane (5.00 ml, 5.50 mmol) dropwise over 5 mins. The solution was stirred for 45 mins at −78° C. after which 16,17-dimethoxy-5,10-violanthrone (516 mg, 1.00 mmol) was added in one portion. The reaction was allowed to warm to room temperature and was stirred overnight. A further 20 ml of THF was added to the reaction followed by SnCl₂.2H₂O (1.50 g, 6.65 mmol) dissolved into 3M HCl (4 ml) added dropwise at 0° C. The reaction allowed to stir for 1 hour while warming to room temperature then quenched with a solution of acetonitrile/1M HCl (50/50, 50 ml) and allowed to stir for 5 mins. The reaction solution was then poured into a solution of acetonitrile/1M HCl (1/1, 150 ml), stirred and a further aliquot of acetonitrile (100 ml) was added. The black precipitate which formed was filtered off and washed with cold acetonitrile (100 ml) to give 300 mg of Compound 15 as a dark green powder (0.506 mmol, 35.4%), m.p. 295-298° C. ¹H NMR (400 MHz, CDCl₃): δ 1.36 (m, 42H), 4.45 (s, 6H), 7.88 (m, 4H), 8.55 (m, 2H), 8.95 (m, 2H). ¹³C NMR (400 MHz, CDCl₃): δ 11.7, 19.0, 56.0, 77.2, 101.4, 102.6, 104.6, 114.1, 117.3, 118.4, 123.3, 124.2, 125.3, 125.9, 126.1, 127.0, 127.4, 127.5, 129.5, 132.0, 132.2, 157.5. MS (EI, 70 eV) m/z 846.4324 (M, C₅₈H₆₂O₂Si₂ requires 846.4288). Anal. Calcd. for C₅₈H₆₂O₂Si₂ C 82.22%, H 7.38%. Found C 82.42%, H 7.55%.

### Example 9

### 5,12-Bis((triisopropylsilyl)ethynyl)rubicene, Compound 17

5,12-Dihyroxyrubicene was prepared by a literature method (Smet, M., Shukla, R., Fülöp, L., and Dehaen, W., Eur. J. Org. Chem., 1998, 2769-2773).

Rubicene-5,12-bistrifluoromethanesulfonate

5,12-Dihyroxyrubicene (150 mg, 0.419 mmol) was dissolved into dry pyridine (15 mL) under nitrogen. The solution was chilled to 0° C. and triflic anhydride (0.280 mL, 1.67 mmol) was added dropwise. The reaction was stirred at 0° C. for 3 hours following which 1M HCl (150 mL) was carefully added. The mixture was extracted with DCM (2×25 mL), the organic layers combined, washed with water (50 mL) and saturated brine solution (50 mL) then filtered through a DryDisk™. The solvent was removed in vacuum, the residue dissolved into 50/50 DCM/Petroleum ether (50 mL) then filtered through a short silica plug eluting with more 50/50 DCM/Petroleum ether. The solvent was then removed under vacuum to give a bright red powder which was used without further purification. (166 mg, 63.8%). m.p. 259-260° C. ¹H NMR (400 MHz, CDCl₃): δ=7.40 (dd, 2H, J=2.36, 8.36 Hz), 7.81 (dd, 2H, J=6.80, 8.52 Hz), 7.84 (d, 2H, J=2.36 Hz), 8.03 (d, 2H, J=6.72 Hz), 8.28 (d, 2H, J=8.40 Hz), 8.50 (d, 2H, J=8.60 Hz). HRMS (EI, 70 eV) m/z 621.9977, C₂₈H₁₂F₆O₆S₂ requires [M]621.9979.

### 5,12-Bis((triisopropylsilyl)ethynyl)rubicene

Rubicene-5,12-bistrifluoromethanesulfonate (120 mg, 0.193 mmol) was dissolved into dry, degassed triethylamine/pyridine (3/2, 10 mL) under nitrogen. Triisopropylsilylacetylene was added followed by copper(I)iodide (4 mg, 10 mol %) and tetrakis(triphenylphosphine)-palladium(0) (11 mg, 5 mol %). The reaction was stirred at 85° C. for three hours then cooled to room temperature. 1M HCl (150 mL) was carefully added and the mixture was extracted with DCM (2×25 mL). The organic layers were combined, washed with water (50 mL) and saturated brine solution (50 mL) then filtered through a DryDisk™. The solvent was removed under vacuum and the resulting residue was chromatographed, silica gel DCM/Petroleum ether (10/90) to give a purple powder (89 mg, 67.4%). m.p. >300° C. ¹H NMR (400 MHz, CDCl₃): δ=1.24 (s, 42H), 7.57 (dd, 2H, J=1.36, 7.88 Hz), 7.73 (dd, 2H, J=6.80, 8.52 Hz), 7.97 (d, 2H, J=6.68 Hz), 8.01 (d, 2H, J=1.04 Hz), 8.17 (d, 2H, J=7.96 Hz), 8.47 (d, 2H, J=8.60 Hz). HRMS (EI, 70 eV) m/z 686.3761, C₄₈H₆₄Si₂ requires [M]686.3764.

### EXAMPLES OF DEVICES OF THE INVENTION

### Experimental

### Apparatus and Definitions

ITO is Tin-doped Indium Oxide

PEDOT/PSS is Poly(3,4-ethylenedioxythiophene): poly(styrenesulfonate)

PCBM is [6,6]-phenyl-C₆₁-butyric acid methyl ester

C₆₀ is (C₆₀-Iₕ)[5,6]fullerene

BCP is 2,9-Dimethyl-4,7-diphenyl-1,10-phenanthroline

V_{oc} is the open circuit voltage of a device

I_{sc} is the short-circuit current of a device

FF is the fill factor of a device

PCE is the power conversion efficiency of a device

ITO coated glass with a sheet resistance of 15 ohms per square was purchased from Kintek. PEDOT/PSS (Baytron P A14083) was purchased from HC Starck. PCBM and C₆₀ were purchased from Nano-C. Calcium pellets and 2,9-dimethyl-4,7-diphenyl-1,10-phenanthroline (BCP) were purchased from Aldrich. Aluminium pellets (99.999%) were purchased from KJ Lesker.

UV-ozone cleaning of ITO substrates was performed using a Novascan PDS-UVT, UV/ozone cleaner with the platform set to maximum height, the intensity of the lamp is greater than 36 mW/cm² at a distance of 100 cm. At ambient conditions the ozone output of the UV cleaner is greater than 50 ppm.

Aqueous solutions of PEDOT/PSS were deposited in air using a Laurell WS-400B-6NPP Lite single wafer spin processor. Organic blends were deposited inside a glovebox using an SCS G3P Spincoater. Film thicknesses were determined using a Dektak 6M Profilometer. Vacuum depositions were carried out using an Edwards 501 evaporator inside a glovebox. Samples were placed on a shadow mask in a tray with a source to substrate distance of approximately 25 cm. The area defined by the shadow mask gave device areas of 0.1 cm². Deposition rates and film thicknesses were measured using a calibrated quartz thickness monitor inside the vacuum chamber. C₆₀ was evaporated from a boron nitride crucible wrapped in a tungsten filament. BCP was evaporated from a baffled tantalum boat. Ca and Al (3 pellets) were evaporated from separate, open tungsten boats.

### Methods

ITO coated glass was cleaned by standing in a stirred solution of 5% (v/v) Deconex 12PA detergent at 90° C. for 20 mins. The ITO was successively sonicated for 10 mins each in distilled water, acetone and iso-propanol. The substrates were then exposed to a UV-ozone clean (at RT) for 10 mins. The PEDOT/PSS solution was filtered (0.2 μm RC filter) and deposited by spin coating at 5000 rpm for 60 sec to give a 38 nm layer. The PEDOT/PSS layer was then annealed on a hotplate in the glovebox at 145° C. for 10 mins. Where used, solutions of the organic blends were deposited onto the PEDOT/PSS layer by spin coating inside a glovebox (H₂O and O₂ levels both <1 ppm). Spinning conditions and film thicknesses were optimised for each blend. The devices were transferred (without exposure to air) to a vacuum evaporator in an adjacent glovebox. Where used, single layers of the organic materials were deposited sequentially by thermal evaporation at pressures below 2×10⁻⁶ mbar. Where used, a layer of Ca (10 nm) was deposited by thermal evaporation at pressures below 2×10⁻⁶ mbar. For all devices a layer of Al (100 nm) was deposited by thermal evaporation at pressures below 2×10−6 mbar. Where noted, the devices were then annealed on a hotplate in the glovebox.

Completed devices were encapsulated with glass and a UV-cured epoxy (Lens Bond type J-91) by exposing to 254 nm UV-light inside a glovebox (H₂O and O₂ levels both <1 ppm) for 10 mins. Prior to electrical testing a small amount of silver paint (Silver Print II, GC electronics, Part no.: 22-023) was deposited onto the connection points of the electrodes. Electrical connections were made using alligator clips.

The cells were tested with an Oriel solar simulator fitted with a 1000W Xe lamp filtered to give an output of 100 mW/cm² at AM 1.5. The lamp was calibrated using a standard, filtered Si cell from Peccell limited (The output of the lamp was adjusted to give a J_{SC} of 0.605 mA). The estimated mismatch factor of the lamp is 0.95. Values were not corrected for this mismatch.

The Incident Photon Collection Efficiency (IPCE) data was collected using an Oriel 150W Xe lamp coupled to a monochromator and an optical fibre. The output of the optical fibre was focussed to give a beam that was contained within the area of the device. The IPCE was calibrated with a standard, unfiltered Si cell.

For both the solar simulator and the IPCE measurements devices were operated using a Keithley 2400 Sourcemeter controlled by Labview Software.

The measurements on the solar simulator gave the cell efficiency under AM 1.5 illumination. The measurements on the IPCE setup gave the cell efficiency at individual wavelengths.

### Results

### Device Example 1

Compound 1 was used in a blend device with PCBM.

Device structure: ITO/PEDOT:PSS (38 nm)/Compound 1:PCBM (1:1) (95 nm)/Ca (10 nm)/Al (100 nm).

A 1 cm³ solution of Compound 1 (10 mg) and PCBM (10 mg) in chloroform was prepared by stirring in air. The solution was filtered (0.2 μm RC filter) and spin coated in air at 4000 rpm.

The I-V curve and IPCE spectrum for the device are shown below:

Device parameters

V_{oc}=920 mV, I_{sc}=3.92 mA/cm², FF=57%, PCE=2.07%

### Device Example 2

Compound 2 was used in a blend device with PCBM.

Device structure: ITO/PEDOT:PSS (38 nm)/Compound 2: PCBM (1:1) (80 nm)/Ca (10 nm)/Al (100 nm).

A 1 cm³ solution of Compound 2 (10 mg) and PCBM (10 mg) in chloroform was prepared by stirring in air. The solution was filtered (0.2 μm RC filter) and spin coated in air at 4000 rpm.

The I-V curve and IPCE spectrum for the device are shown below:

Device parameters

V_{oc}=861 mV, I_{sc}=4.65 mA/cm², FF=45%, PCE=1.81%

### Device Example 3

Compound 1 was used in a layered device with C₆₀.

Device structure: ITO/PEDOT:PSS (38 nm)/Compound 1 (45 nm)/C₆₀ (40 nm)/BCP (10 nm)/Al (100 nm).

The Compound 1 layer was prepared by thermal evaporation from a baffled tantalum boat at pressures below 2×10⁻⁶ mbar.

The I-V curve and IPCE spectrum for the device are shown below:

Device parameters

V_{oc}=721 mV, I_{sc}=2.00 mA/cm², FF=46%, PCE=0.66%

### Device Example 4

Compound 4 was used in a blend device with PCBM.

Device structure: ITO/PEDOT:PSS (38 nm)/Compound 4: PCBM (1:1) (80 nm)/Ca (10 nm)/Al (100 nm).

A 1 cm³ solution of Compound 4 (10 mg) and PCBM (10 mg) in chlorobenzene was prepared by stirring in a glovebox. The solution was filtered (0.2 μM RC filter) and spin coated in a glovebox at 3000 rpm.

Device parameters

V_{oc}=414 mV, I_{sc}=0.13 mA/cm², FF=30%, PCE=0.16%

### Device Example 5

Compound 5 was used in a blend device with PCBM.

Device structure: ITO/PEDOT:PSS (38 nm)/Compound 5: PCBM (1:1) (80 nm)/Ca (10 nm)/Al (100 nm).

A 1 cm³ solution of Compound 5 (10 mg) and PCBM (10 mg) in chlorobenzene was prepared by stirring in a glovebox. The solution was filtered (0.2 μm RC filter) and spin coated in a glovebox at 3000 rpm.

Device parameters

V_{oc}=404 mV, I_{sc}=0.91 mA/cm², FF=33%, PCE=0.12%

### Device Example 6

Compound 7 was used in a blend device with PCBM.

Device structure: ITO/PEDOT:PSS (38 nm)/Compound 7: PCBM (1:1) (80 nm)/Ca (10 nm)/Al (100 nm).

A 1 cm³ solution of Compound 7 (10 mg) and PCBM (10 mg) in chloroform was prepared by stirring in a glovebox. The solution was filtered (0.2 μm RC filter) and spin coated in a glovebox at 2000 rpm.

Device parameters

V_{oc}=711 mV, I_{sc}=3.44 mA/cm², FF=32%, PCE=0.79%

### Device Example 7

Compound 15 was used in a blend device with PCBM.

Device structure: ITO/PEDOT:PSS (38 nm)/Compound 15: PCBM (1:1) (80 nm)/Ca (10 nm)/Al (100 nm).

A 1 cm³ solution of Compound 15 (10 mg) and PCBM (10 mg) in chlorobenzene was prepared by stirring in a glovebox. The solution was filtered (0.2 μm RC filter) and spin coated in air at 3000 rpm.

Device parameters

V_{oc}=752 mV, I_{sc}=2.43 mA/cm², FF=33%, PCE=0.60%

### Device Example 8

Compound 17 was used in a blend device with PCBM.

Device structure: ITO/PEDOT:PSS (38 nm)/Compound 17: PCBM (1:4) (164 nm)/Ca (10 nm)/Al (100 nm).

A 2 cm³ solution of Compound 17 (10 mg) and PCBM (40 mg) in chloroform was prepared by stirring in a glovebox. The solution was filtered (0.2 μm RC filter) and spin coated in a glovebox at 4000 rpm.

Device parameters

V_{oc}=920 mV, I_{sc}=0.32 mA/cm², FF=45%, PCE=0.13%

### Example of Evidence of the Absence of Reaction Between Electron Donor Polycyclic Aromatic Compounds and Electron Acceptor Fullerene Derivatives Used to Make Devices of the Invention

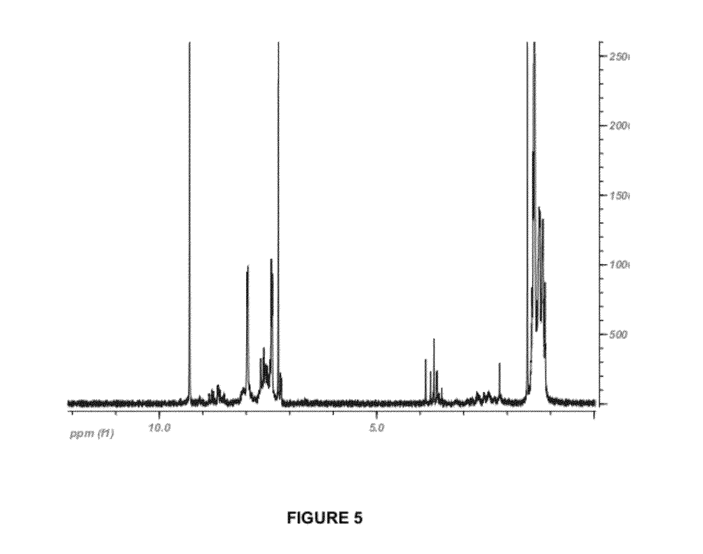

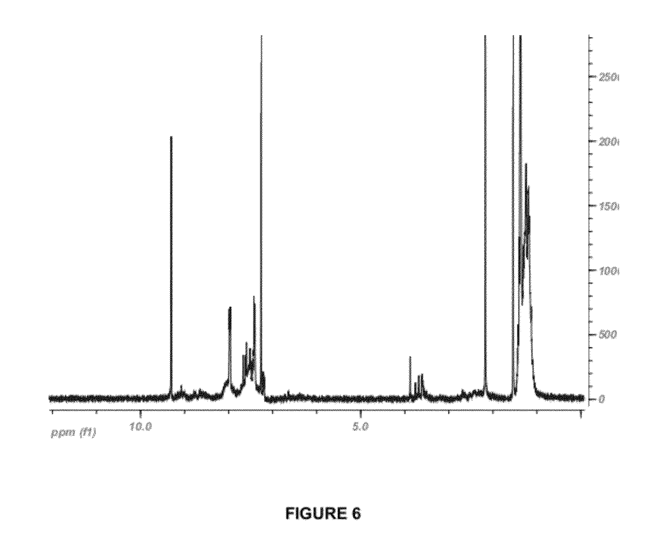

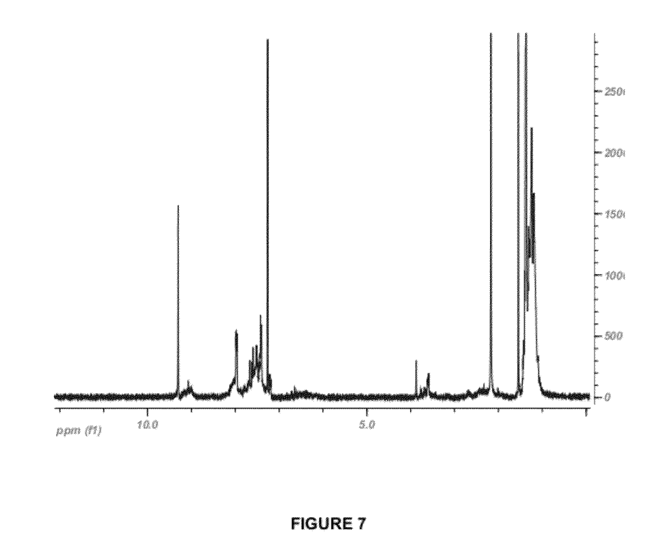

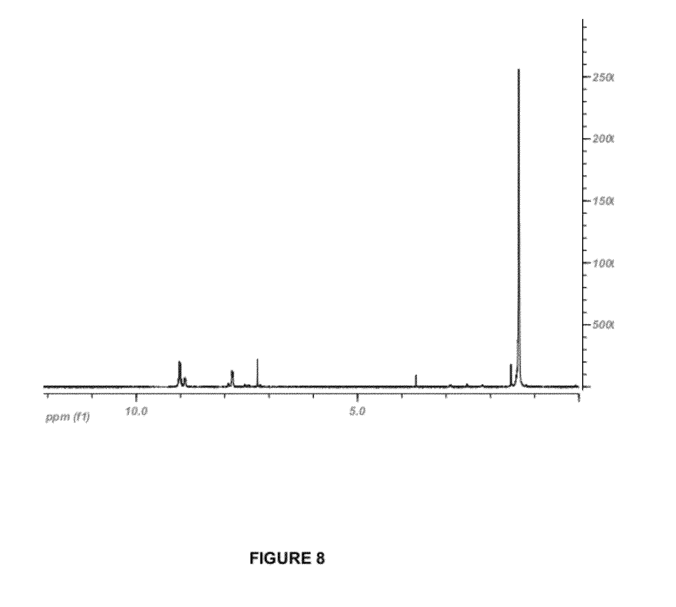

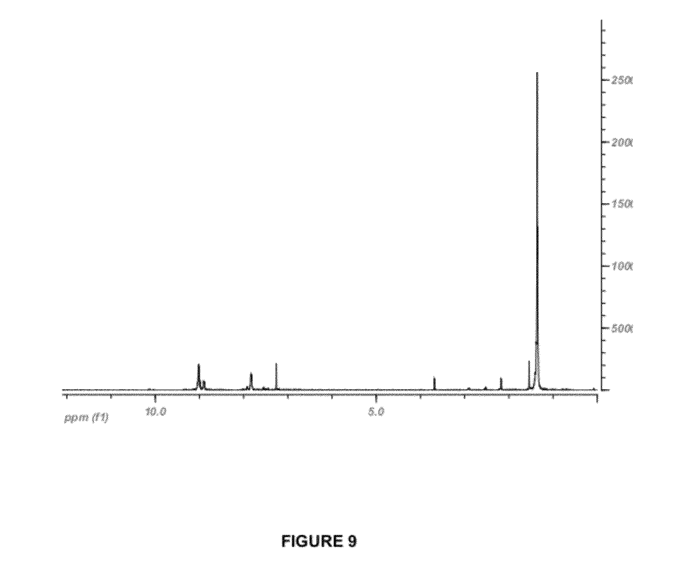

2 mg each of 6,13-bis(triisopropylsilylethynyl)pentacene (TIPSPEN) and [6,6]-phenyl-C61-butyric acid methyl ester (PCBM) were dissolved into 1 ml of deuterated chloroform and the mixture was allowed to stand under ambient laboratory conditions and monitored by ¹H NMR for any reaction. An identical experiment was preformed using 7,14-tis((triisopropylsilyl)ethynyl)dibenzo[b,det]-chrysene (Compound 1) in place of TIPSPEN. The TIPSPEN/PCBM mixture clearly underwent a reaction or multiple reactions immediately upon mixing (FIG. 5). Further reactions were observed after a 24 hour period (FIG. 6) and again upon sonication and heating at 50° C. for 30 minutes (FIG. 7). No reactions were observed for the Compound 1/PCBM mixture and the NMR spectra remained unchanged under the same conditions as for the TIPSPEN/PCBM mixture (FIGS. 8, 9 10).

Whilst the invention has been described in terms of exemplary embodiments, those skilled in the art will recognise that the invention can be practiced with modifications within the spirit and scope of the appended claims.

1. A photosensitive optoelectronic device including at least one compound comprising at least one polycyclic aromatic substructure wherein at least two of the ring atoms of the said polycyclic aromatic substructure are each common to three rings, said compound being directly substituted with at least one alkynyl group.

2. The device of claim 1 wherein the compound is substituted with at least two alkynyl groups, wherein at least two of said alkynyl groups are located in non-adjacent substitution positions.

3. The device of claim 1 wherein at least one polycyclic aromatic substructure has at least five aromatic rings.

4. The device of claim 1 wherein at least one polycyclic aromatic substructure has at least six aromatic rings.

5. The device of claim 1 wherein the compound is photosensitive.

6. The device of claim 1 wherein the compound comprises additional substituents selected from the group consisting of halogen, nitrile and the following optionally substituted moieties; alkyl, cycloalkyl, cycloalkylalkyl, alkoxy, cycloalkoxy, cycloalkylalkoxy, alkenyl, aryl, aryoxy, arylalkyl, heterocyclyl, heterocyclylalkyl, heteroaryl, heteroarylalkyl, alkoxyalkyl, cycloalkkoxyalkyl, aryloxyalkyl, haloalkyl, trialkylsilyl dialkylarylsilyl, alkyldiarylsilyl or triarylsilyl.

7. The device of claim 1 wherein the substructure comprises an alternant polycyclic benzenoid aromatic ring system.

8. The device of claim 7 wherein the alternant polycyclic benzenoid ring system comprises a substructure template selected from one or more of the group consisting of:

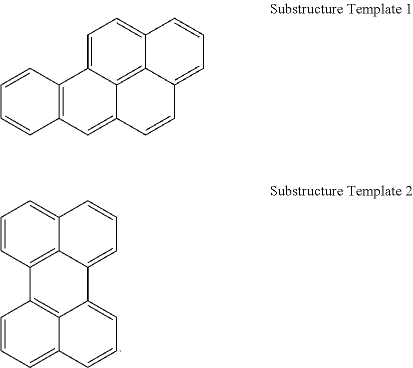

9. The device of claim 8 wherein the alternant polycyclic benzenoid ring system is selected from one or more of the group consisting of:

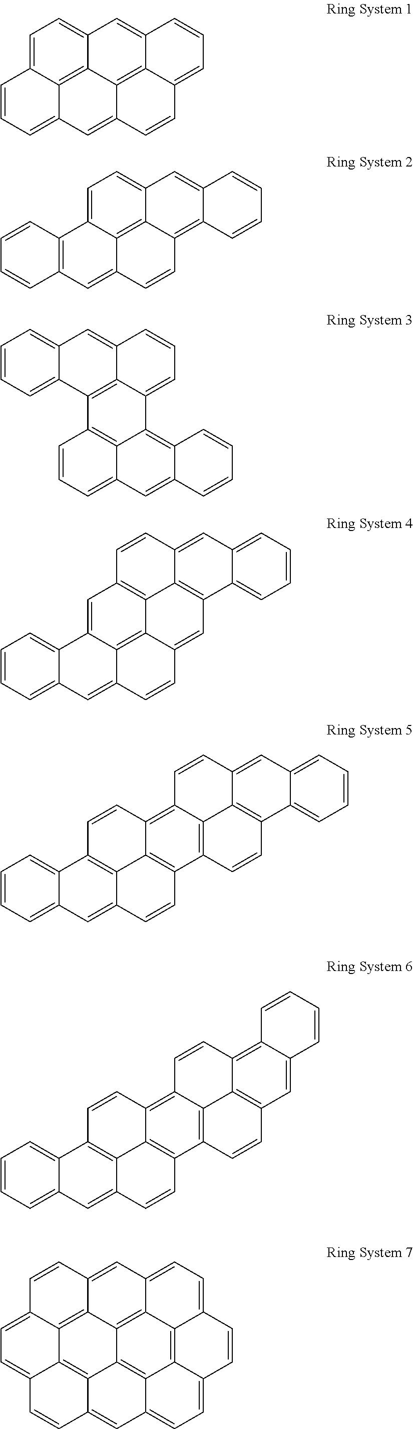

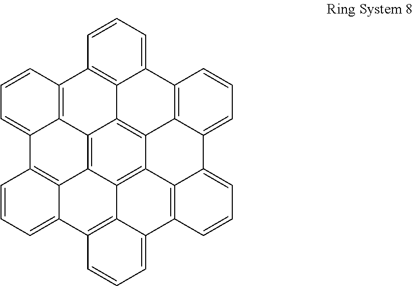

10. The device of claim 1 wherein the substructure comprises rings in addition to or alternative to benzenoid rings.

11. The device of claim 10 wherein the substructure has the following structure:

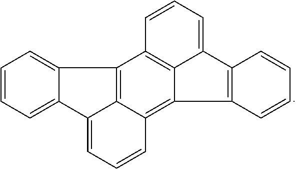

12. The device of claim 1 wherein the compound contains at least two alkynyl substituents, —C≡C—X(R)ₙ wherein X is an atom selected from groups IIIa to VIb of the Periodic Table of the Elements and R is independently selected from the group consisting of hydrogen and the following optionally substituted moieties: alkyl, cycloalkyl, cycloalkylalkyl, aryl, arylalkyl, heterocyclyl, heterocyclylalkyl, heteroaryl, heteroarylalkyl, alkoxyalkyl, cycloalkkoxyalkyl, aryloxyalkyl, haloalkyl, trialkylsilyl, dialkylarylsilyl, alkyldiarylsilyl and triarylsilyl and n is an integer from 1 to v−1 wherein v is the valency of X.

13. The device of claim 12 wherein the alkynyl substituents are of the form —C≡C—X(R)₃ wherein X is C or Si and R is independently selected from the group consisting of hydrogen and the following optionally substituted moieties: alkyl, cycloalkyl, cycloalkylalkyl, aryl, arylalkyl, heterocyclyl, heterocyclylalkyl, heteroaryl, heteroarylalkyl, alkoxyalkyl, cycloalkkoxyalkyl, aryloxyalkyl, haloalkyl, trialkylsilyl dialkylarylsilyl, alkyldiarylsilyl and triarylsilyl.

14. The device of claim 1 wherein the compound is selected from one or more of the group consisting of

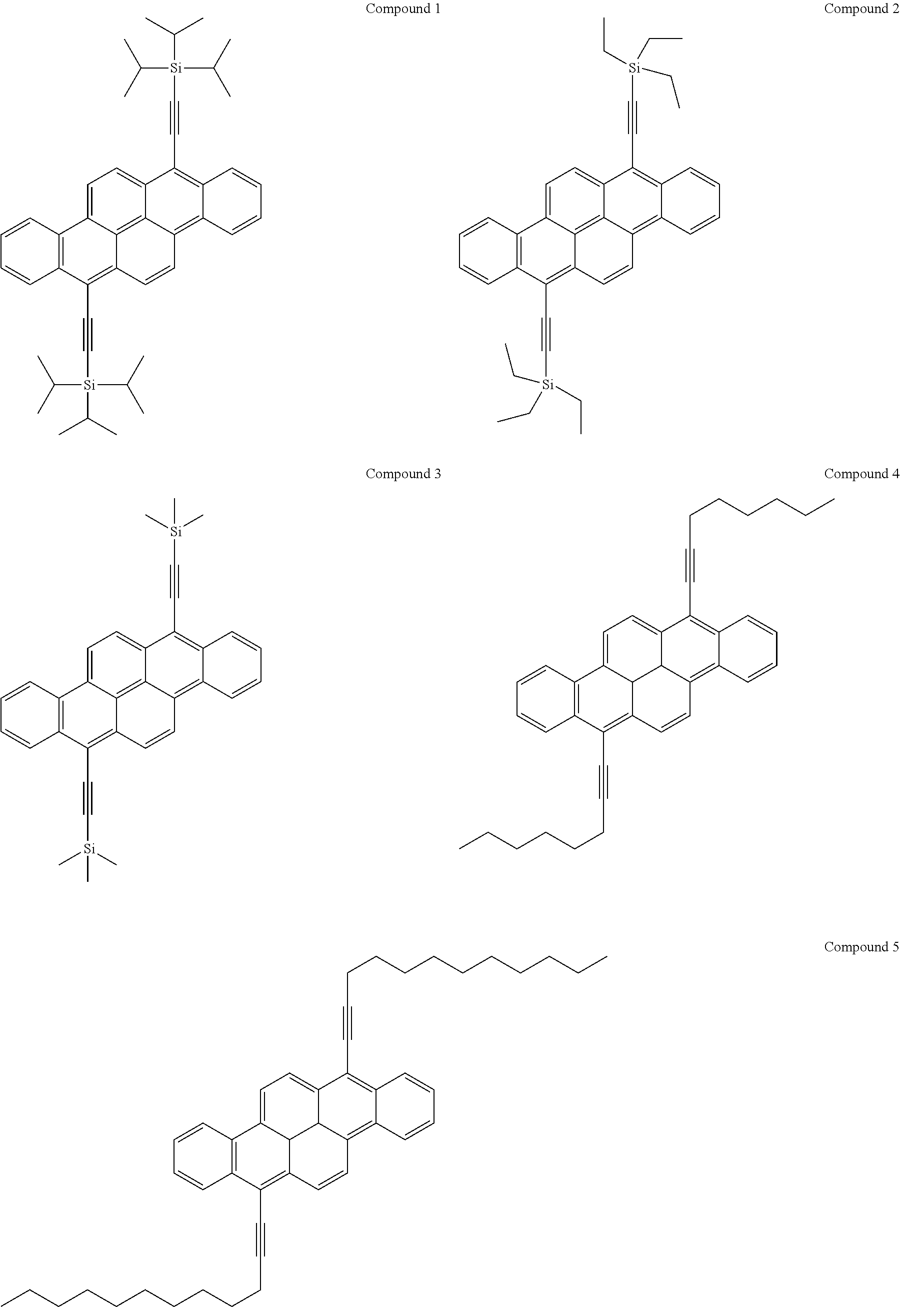

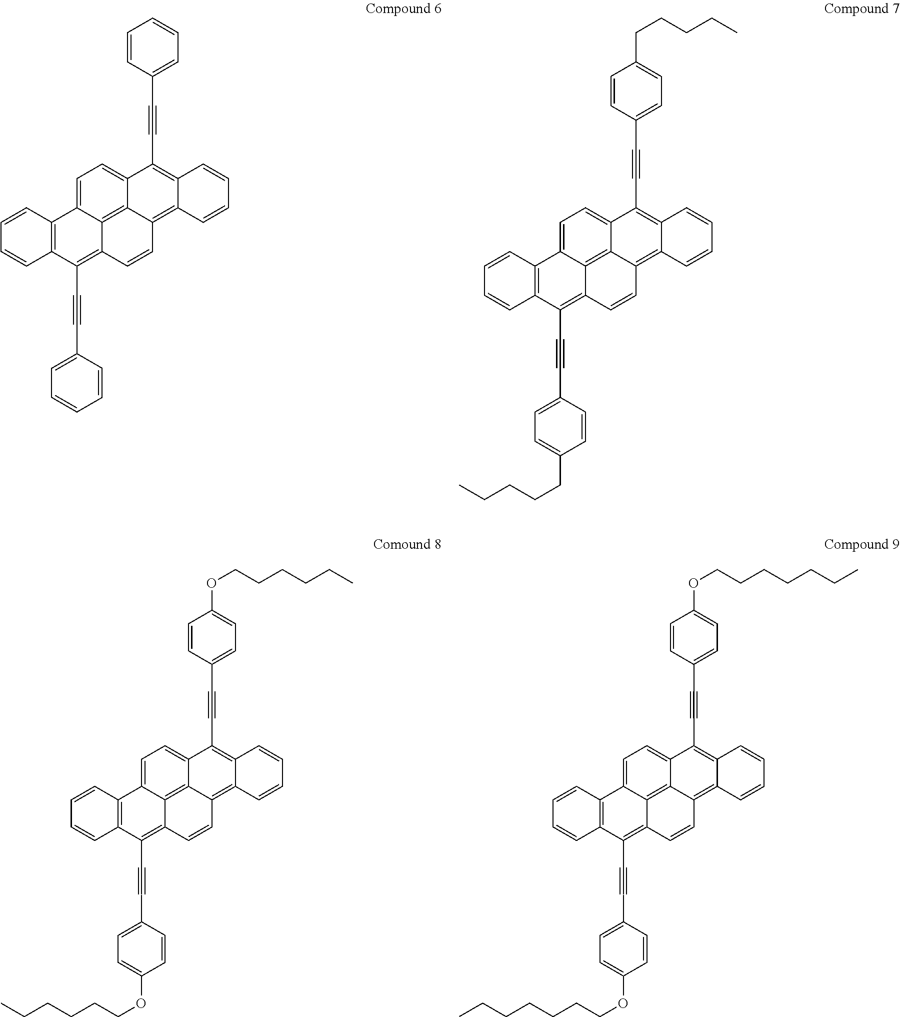

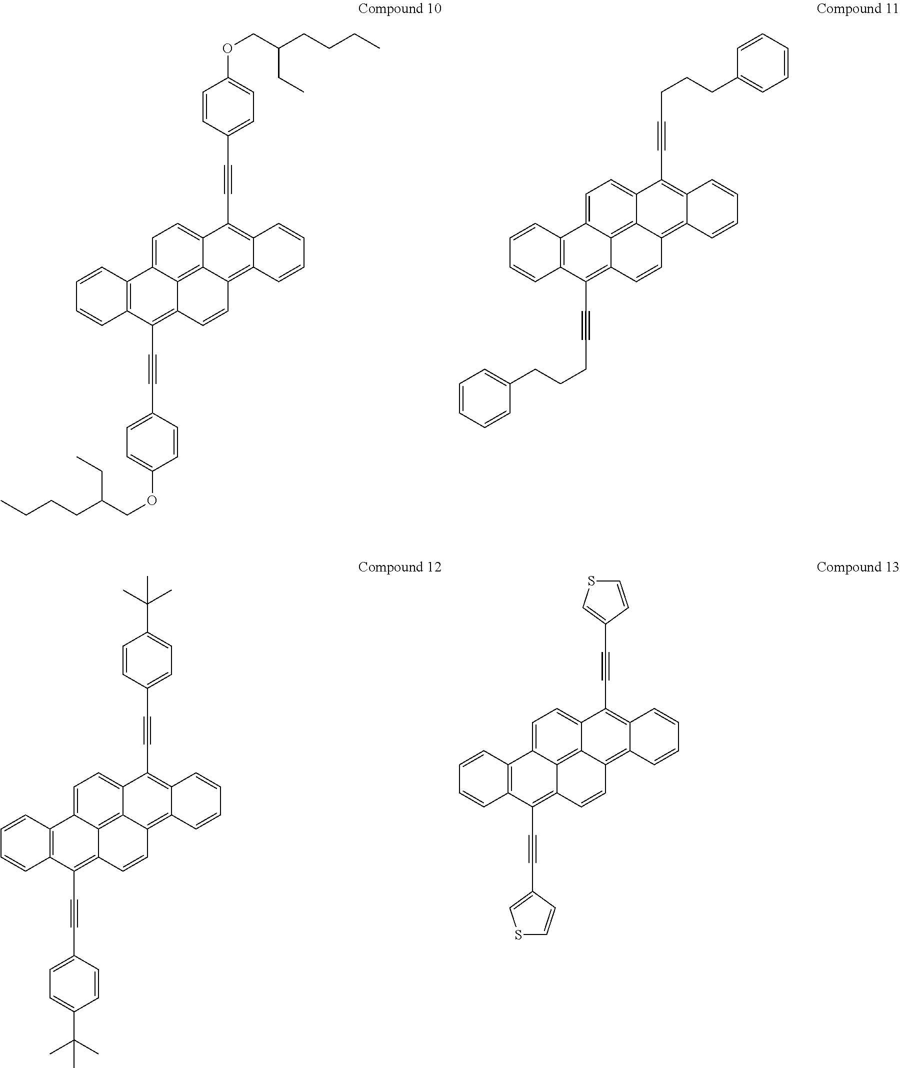

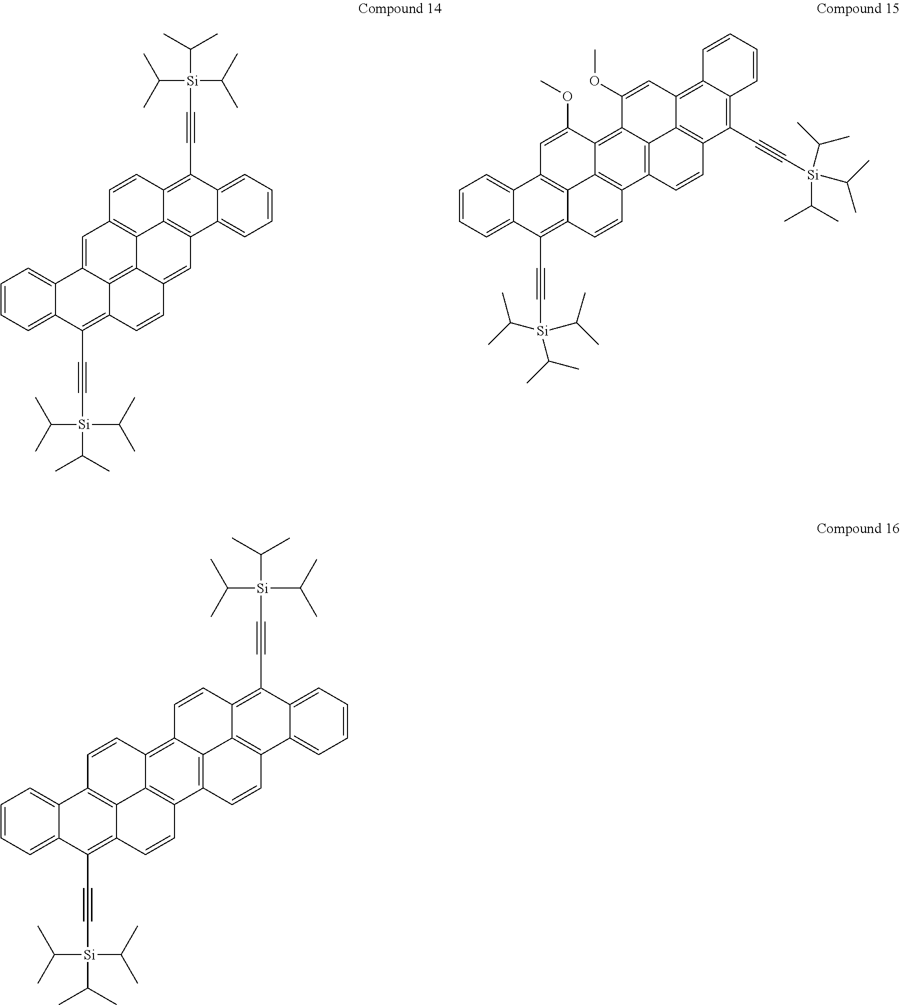

15. The device of claim 1 wherein the compound is:

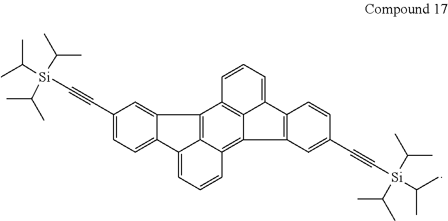

16. The device of claim 12 wherein if the alkynyl group of the form —C≡C—X(R)ₙ is located at the peripheral carbon atom of rubicene then X is not a carbon atom.

17. The device of claim 1 further comprising one or more electron donors or electron acceptors.

18. The device of claim 1 wherein the compound does not undergo chemical reaction, in particular a carbon-carbon bond forming reaction, with another component of the device.

19. The device of claim 1 wherein the device includes fullerene or a fullerene derivative.

20. The device of claim 19 wherein the compound does not undergo a chemical reaction, such as a cycloaddition reaction, with fullerene or the fullerene derivative.

21. The device of claim 1, wherein the device is selected from the group consisting of a photovoltaic devices, photoconductive devices and photodetector devices.

22-23. (canceled)

24. The device of claim 21 further comprising a pair of electrodes, and one or more layers of semiconducting material between said electrodes, wherein at least one of the layers including the compound.

25. The device of claim 24 wherein at least two layers of semiconducting materials are provided between the electrodes, said layers forming a heterojunction and at least one of said layers comprising a photosensitive semiconducting material which includes the compound.

26. The device of claim 25 wherein each of said at least two layers includes the compound.

27. The device of any claim 24 wherein another layer of the device is an electron accepting fullerene derivative and said compound is an electron donating compound which does not undergo a chemical reaction with the fullerene derivative.

28. The device of claim 24 wherein the layer or at least one of the layers of semiconducting material includes a mixture or blend of the compound and another organic semiconducting material.

29. The device of claim 28 wherein the mixture or blend includes an electron accepting fullerene derivative and the compound is an electron donating compound which does not undergo a chemical reaction with the fullerene derivative.

30. Use of the device of claim 18 in the generation of solar power.
